(19) United States
(12) Patent Application Publication
(10) Pub. No.: US 2026/0036666 A1
(43) Pub. Date: Feb. 5, 2026

(54) SYSTEMS, METHODS, AND DEVICES FOR COLLABORATIVE LOCATION DETERMINATION

(71) Applicant: Apple Inc., Cupertino, CA (US)

(72) Inventors: Till Hendrik MÜLLER, Munich (DE); Nabil AKDIM, Munich (DE); Gencer CILI, San Jose, CA (US)

(21) Appl. No.: 18/791,277

(22) Filed: Jul. 31, 2024

(51) Int. Cl. G01S 5/10; G01R 31/36

(52) U.S. Cl. CPC G01S 5/10; G01R 31/36

(57) ABSTRACT

Techniques are provided for collaboratively determining a location estimate for a UE. A UE can determine that it is moving with one or more other wireless device. The UE can determine a location estimate based upon location information and location metadata. The UE can determine an uncertainty of the location estimate based upon values of the location information and the location metadata. These and many other features and examples are described.

### FIELD

This disclosure relates to wireless communication networks and devices.

### BACKGROUND

Wireless communication networks and wireless communication services are becoming increasingly dynamic, complex, and ubiquitous. For example, some wireless communication networks can be developed to implement fifth generation (5G) or new radio (NR) technology, sixth generation (6G) technology, and so on. Such technology can include solutions for enabling network nodes and access points to communicate with one another in a variety of ways. In some scenarios, UEs can communicate with a plurality of base stations.

### BRIEF DESCRIPTION OF THE DRAWINGS

The present disclosure will be readily understood and enabled by the detailed description and accompanying figures of the drawings. Like reference numerals can designate like features and structural elements. Figures and corresponding descriptions are provided as non-limiting examples of aspects, implementations, etc., of the present disclosure, and references to “an” or “one” aspect, implementation, etc., may not necessarily refer to the same aspect, implementation, etc., and can mean at least one, one or more, etc.

FIG. 1 is a diagram of an example overview of collaborative location estimation according to one or more implementations described herein.

FIG. 2 is a diagram of an example network according to one or more implementations described herein.

FIG. 3 is a diagram of an example process for exchanging and updating location estimates according to one or more implementations described herein.

FIG. 4 is a diagram of an example process for sharing location information between UEs in a group of UEs, according to one or more implementations described herein.

FIG. 5 is a diagram of an example table of location information according to one or more implementations described herein.

FIG. 6 is a diagram of an example process for selecting a location estimate source according to one or more implementations described herein.

FIG. 7 is a diagram of an example process for selecting a location estimate source according to one or more implementations described herein.

FIG. 8 is a diagram of an example of a group of UEs coordinating collection and sharing of location information according to one or more implementations described herein.

FIG. 9 is a diagram of an example of components of a device according to one or more implementations described herein.

FIG. 10 is a diagram of example interfaces of baseband circuitry according to one or more implementations described herein.

FIG. 11 is a block diagram illustrating components, according to one or more implementations described herein, able to read instructions from a machine-readable or computer-readable medium (e.g., a non-transitory machine-readable storage medium) and perform any one or more of the methodologies discussed herein.

FIG. 12 is a diagram of a process of a UE determining a location estimate according to one or more implementations described herein.

FIG. 13 is a diagram of a process of a UE determining, distributing, and implementing a location estimate sharing schedule with a UE group according to one or more implementations described herein.

FIG. 14 is a diagram of a process of a UE determining a location estimate according to one or more implementations described herein.

### DETAILED DESCRIPTION

The following detailed description refers to the accompanying drawings. Like reference numbers in different drawings can identify the same or similar features, elements, operations, etc. Additionally, the present disclosure is not limited to the following description as other implementations can be utilized, and structural or logical changes made, without departing from the scope of the present disclosure.

Wireless networks can include user equipment (UEs) capable of communicating with base stations, wireless routers, satellites, and other network nodes. Such devices can operate in accordance with one or more communication standards, such as 2nd generation (2G), 3rd generation (3G), 4th generation (4G) (e.g., long-term evolution (LTE)), and/or 5th generation (5G) (e.g., new radio (NR)) communication standards of the 3rd generation partnership project (3GPP). A UE can refer to a smartphone, tablet computer, wearable wireless device, a vehicle capable of wireless communications, and/or another type of a broad range of wireless-capable device.

Some UEs include circuitry configured to geolocate the UEs, identifying the geographic position of the UEs in the world. UEs can determine their geographic position using different sensing modalities, including a global navigation satellite system (GNSS) (e.g., a global positioning system (GPS), Galileo®, globalnaya navigatsionnaya sputnikovaya sistema (GLONASS®), and/or BeiDou®), by communicating with base stations, using Bluetooth®, and/or the like. In some scenarios, UEs can be configured to detect the presence of other UEs that are physically close together. The UEs can initiate peer-to-peer (P2P) communication with one another, without requiring an intermediary device. For example, UEs can include circuitry and can be configured to communicate over a sidelink (SL) connection, Bluetooth®, via Zigbee®, via a mesh networking protocol, near-field communication, and/or the like. In some scenarios, the UEs can periodically broadcast an identifier using a first communication protocol, and when that identifier is received at another UE, the UEs can initiate communication using a second communication protocol, different from the first communication protocol.

UEs can in some instances be moving together. For example, a group of peers walking together can each carry a mobile phone, passengers riding public transportation can each carry a mobile phone and/or tablet, and a family can be driving together in a car, each family member with a mobile phone. In some examples, the UEs can communicate with each other, and individually or collectively determine that the UEs are moving together. In response to determining the similar or same movement, the UEs can configure themselves to exchange estimates of their respective locations. By exchanging the location estimates, the UEs can more efficiently and accurately estimate their respective locations by leveraging location information that is captured by other UEs in the group.

By using the location information from other UEs in the group, an individual UE can reduce power consumption and processing otherwise required to sense the location of the UE. Moreover, using location information from the other UEs can reduce a size of an area or region of uncertainty associated with geolocation modalities. For example, a region of uncertainty of a location estimate based upon knowledge that a UE is connected to a particular base station (which can be associated with a relatively larger region of uncertainty) by supplementing that location estimate with a different location estimate obtained from a different UE that was determined using GNSS, which can be associated with a relatively smaller region of uncertainty.

Current techniques and solutions fail to address the need for exchange of rich information that can accurately estimate a location of a device in a group of devices while weighing the possibility and degree of uncertainty associated with location measurements. Current techniques and solutions further fail to address the need for procedures to establish, and/or distribute responsibilities of detecting and sharing location data between the group of devices.

Techniques described herein address the deficiencies of currently available technology by providing solutions that enable a UE to collaboratively determine its location by communicating with a group of other UEs. In some scenarios, UEs can establish that they are traveling together and can thereafter form a group of devices. In some scenarios, the UEs can share location information and supplemental information or metadata that provides characteristics of the UE and/or a sensing modality used to generate the location information. In some scenarios, UEs can update and/or determine their location based upon location information and supplemental information or metadata receive from other UEs in the group. In some scenarios, UEs can combine several location estimates to determine their location. In some scenarios, the UEs can enable, change configurations of, and/or disable localization circuitry at other UEs in the group to distribute or offload processing and/or sensing required to determine a location of the group of UEs. These and many other features and examples are described below with reference to the Figures.

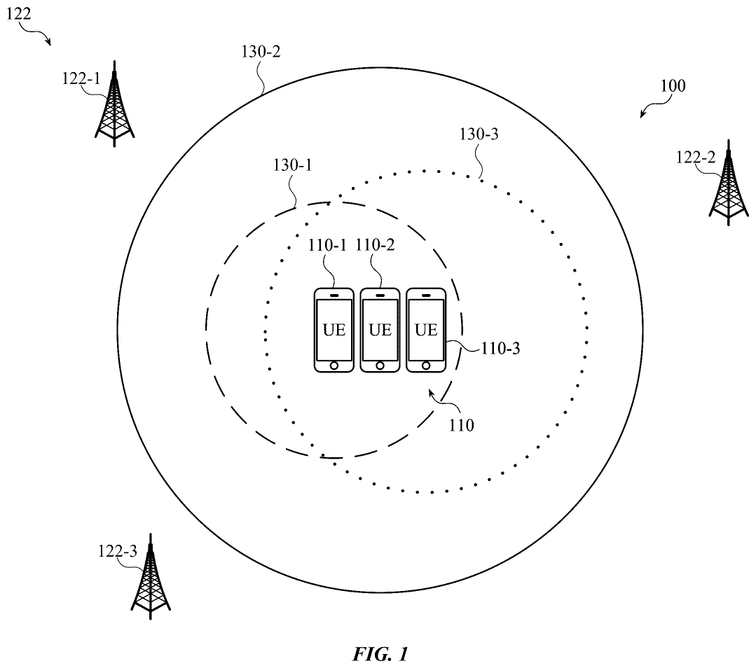

FIG. 1 is a diagram of an example of overview 100 of collaborative location estimation according to one or more implementations described herein. As shown, overview 100 can include UE 110-1, UE 110-2, and UE 110-3, and base station 122-1, base station 122-2, and base station 122-3. In some implementations, one or more of the UEs 110 can be in communication with one or more of the base stations 122. Some or all of the UEs 110 can be in communication with each other. In some implementations, some or all of the UEs 100 can be in communication with additional or alternative entities different from the base stations, such as one or more satellites, localization beacons, and/or the like.

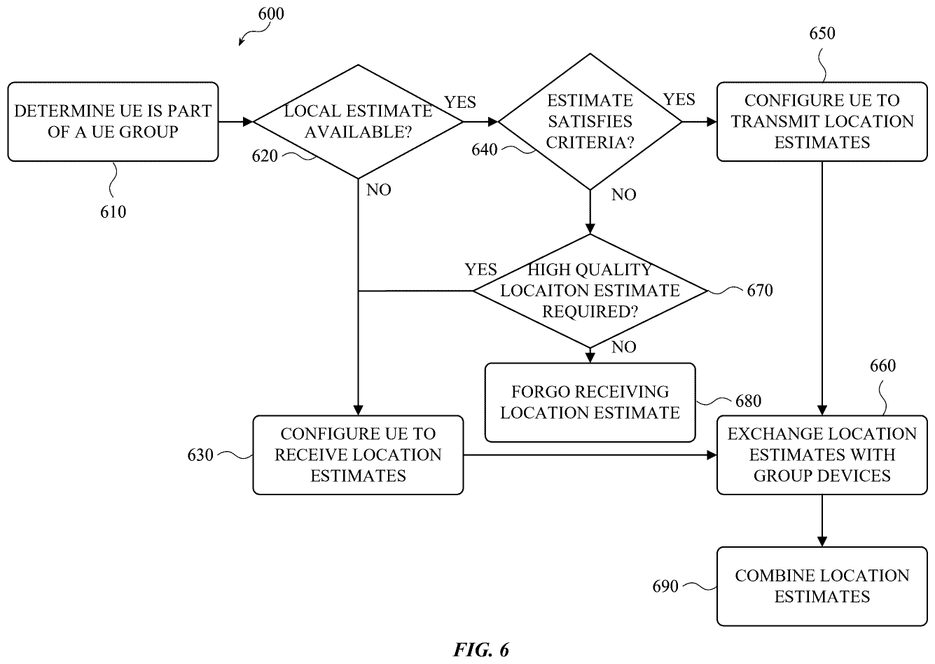

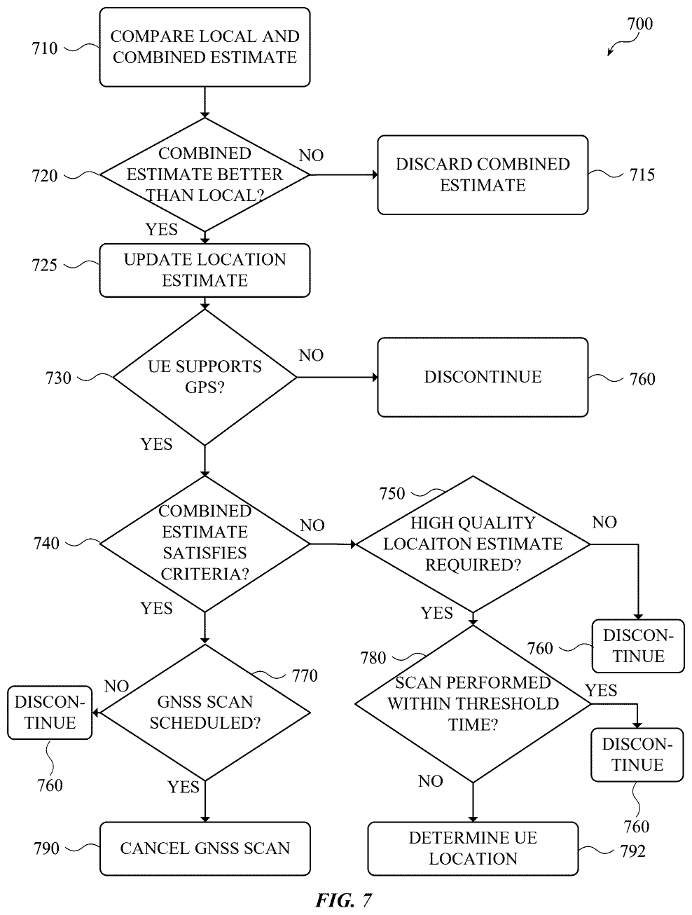

UEs 110 can individually determine and/or store a location estimate of the device. For example, UE 110-1 can estimate that it is geolocated at a first location within uncertainty region 130-1. A location estimate can be an estimated or predicted of UE 110 (e.g., longitude and latitude coordinates). An uncertainty region can be an area around the location estimate. Uncertainty region 130-1 can represent an accuracy of a location estimate generated by UE 110-1. It is understood, however, that the location estimate is not inherently inaccurate, but that due to variance in signal propagation, tolerances in circuitry, variation in an operating environment of UE 110-1, and/or the like, there can be a region of uncertainty that surrounds the estimate of the location of UE 110-1. In some scenarios, based upon a combination of one or more of the aforementioned factors, the size, shape, and/or position of an uncertainty region can change. Additionally or alternatively, based upon metadata associated with location information, UE 110-1 can modify the size and/or shape of the uncertainty region, as described in additional detail with reference to FIGS. 6 and 7. Uncertainty region 130-1 can be associated with a geolocation technology that is typically more precise than other sensing technologies (e.g., GNSS is typically more precise than Internet protocol (IP) based geolocation), and is therefore smaller than uncertainty region 130-2.

Uncertainty region 130-2 can be a region of uncertainty surrounding a location estimate of UE 110-2 that is determined by UE 110-2. Similarly, uncertainty region 130-3 can be a region of uncertainty surrounding a location estimate of UE 110-3 that is determined by UE 110-3. Uncertainty regions 130-1, 130-2, and 130-3 can each correspond to different types of sensing technologies used to determine the location of corresponding UEs. UEs 110-1, 110-2, and 110-3 can be co-located, and/or can be traveling together. As described further herein, the UEs 110 can communicate with each other to exchange location estimates and/or information indicative of a corresponding uncertainty region associated with the respective location estimates. This can, for example, help reduce power consumption of each device when attempting to geolocate an individual UE 110.

The techniques described herein also include other features and solutions. For example, the techniques described herein include solutions for configuring UEs 110 in a group to determine and/or share their locations with the group of UEs 100 at different times. Additionally or alternatively, the techniques described herein include solutions for enabling UE 110 to provide location estimates for tother UEs 110 in the group. Accordingly, many additional features and benefits of the techniques described herein are discussed below reference to the examples and Figures below.

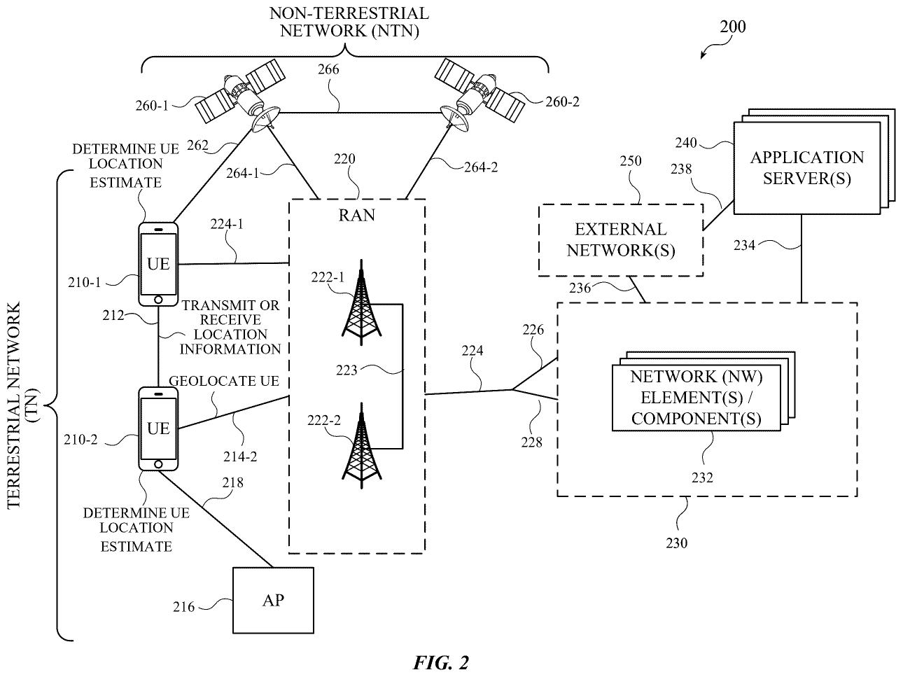

FIG. 2 is an example network 200 according to one or more implementations described herein. Example network 200 can include UEs 210-1, 210-2, etc. (referred to collectively as “UEs 210” and individually as “UE 210”), a radio access network (RAN) 220, a core network (CN) 230, application servers 240, external networks 250, and satellites 260-1, 260-2, etc. (referred to collectively as “satellites 260” and individually as “satellite 260”). As shown, network 200 can include a non-terrestrial network (NTN) comprising one or more satellites 260 (e.g., of a global navigation satellite system (GNSS)) in communication with UEs 210 and RAN 220.

The systems and devices of example network 200 can operate in accordance with one or more communication standards, such as 2nd generation (2G), 3rd generation (3G), 4th generation (4G) (e.g., long-term evolution (LTE)), and/or 5th generation (5G) (e.g., new radio (NR)) communication standards of the 3rd generation partnership project (3GPP). Additionally, or alternatively, one or more of the systems and devices of example network 200 can operate in accordance with other communication standards and protocols discussed herein, including future versions or generations of 3GPP standards (e.g., sixth generation (6G) standards, seventh generation (7G) standards, etc.), institute of electrical and electronics engineers (IEEE) standards (e.g., wireless metropolitan area network (WMAN), worldwide interoperability for microwave access (WiMAX), etc.), and more.

As shown, UEs 210 can include smartphones (e.g., handheld touchscreen mobile computing devices connectable to one or more wireless communication networks). Additionally, or alternatively, UEs 210 can include other types of mobile or non-mobile computing devices capable of wireless communications, such as personal data assistants (PDAs), pagers, laptop computers, desktop computers, wireless handsets, etc. In some implementations, UEs 210 can include internet of things (IoT) devices (or IoT UEs) that can comprise a network access layer designed for low-power IoT applications utilizing short-lived UE connections. Additionally, or alternatively, an IoT UE can utilize one or more types of technologies, such as machine-to-machine (M2M) communications or machine-type communications (MTC) (e.g., to exchanging data with an MTC server or other device via a public land mobile network (PLMN)), proximity-based service (ProSe) or device-to-device (D2D) communications, sensor networks, IoT networks, and more. Depending on the scenario, an M2M or MTC exchange of data can be a machine-initiated exchange, and an IoT network can include interconnecting IoT UEs (which can include uniquely identifiable embedded computing devices within an Internet infrastructure) with short-lived connections. In some scenarios, IoT UEs can execute background applications (e.g., keep-alive messages, status updates, etc.) to facilitate the connections of the IoT network.

UEs 210 can communicate and establish a connection with one or more other UEs 210 via one or more wireless channels 212, each of which can comprise a physical communications interface/layer. The connection can include an M2M connection, MTC connection, D2D connection, SL connection, etc. The connection can involve a PC5 interface. In some implementations, UEs 210 can be configured to discover one another, negotiate wireless resources between one another, and establish connections between one another, without intervention or communications involving RAN node 222 or another type of network node. In some implementations, discovery, authentication, resource negotiation, registration, etc., can involve communications with RAN node 222 or another type of network node.

UEs 210 can use one or more wireless channels 212 to communicate with one another. As described herein, UE 210 can communicate with RAN node 222 to request SL resources. RAN node 222 can respond to the request by providing UE 210 with a dynamic grant (DG) or configured grant (CG) regarding SL resources. A DG can include a grant based on a grant request from UE 210. A CG can involve a resource grant without a grant request and can be based on a type of service being provided (e.g., services that have strict timing or latency requirements). UE 210 can perform a clear channel assessment (CCA) procedure based on the DG or CG, select SL resources based on the CCA procedure and the DG or CG; and communicate with another UE 210 based on the SL resources. The UE 210 can communicate with RAN node 222 using a licensed frequency band and communicate with the other UE 210 using an unlicensed frequency band.

UEs 210 can communicate and establish a connection with RAN 220, which can involve one or more wireless channels 214-1 and 214-2, each of which can comprise a physical communications interface/layer. In some implementations, a UE can be configured with dual connectivity (DC) as a multi-radio access technology (multi-RAT) or multi-radio dual connectivity (MR-DC), where a multiple receive and transmit (Rx/Tx) capable UE can use resources provided by different network nodes (e.g., 222-1 and 222-2) that can be connected via non-ideal backhaul (e.g., where one network node provides NR access and the other network node provides either E-UTRA for LTE or NR access for 5G). A network node can be referred to herein as a base station 222. In such a scenario, one network node can operate as a master node (MN) and the other as the secondary node (SN). The MN and SN can be connected via a network interface, and at least the MN can be connected to the CN 230. Additionally, at least one of the MN or the SN can be operated with shared spectrum channel access, and functions specified for UE 210 can be used for an integrated access and backhaul mobile termination (IAB-MT). Similar for UE 210, the IAB-MT can access the network using either one network node or using two different nodes with enhanced dual connectivity (EN-DC) architectures, new radio dual connectivity (NR-DC) architectures, or the like. In some implementations, a base station (as described herein) can be an example of network node 222. In some scenarios, RAN 220 can coordinate with core network 230 via interfaces 224, 226, and/or 228.

In some scenarios, UE 210 can perform one or more operations enable collaborative estimation of UE locations. The operation(s) can include determining that UE 210 is moving with other UEs 210 and forming a group with the other UEs 210. Additionally, UEs 210 can determine their locations collaboratively, based on location information and/or location information metadata exchanged between UEs 210.

As shown, UE 210 can also, or alternatively, connect to access point (AP) 216 via connection interface 218, which can include an air interface enabling UE 210 to communicatively couple with AP 216. AP 216 can comprise a wireless local area network (WLAN), WLAN node, WLAN termination point, etc. The connection 216 can comprise a local wireless connection, such as a connection consistent with any IEEE 702.11 protocol, and AP 216 can comprise a wireless fidelity (Wi-Fi®) router or other AP. While not explicitly depicted in FIG. 2, AP 216 can be connected to another network (e.g., the Internet) without connecting to RAN 220 or CN 230. In some scenarios, UE 210, RAN 220, and AP 216 can be configured to utilize LTE-WLAN aggregation (LWA) techniques or LTE WLAN radio level integration with IPsec tunnel (LWIP) techniques. LWA can involve UE 210 in RRC_CONNECTED being configured by RAN 220 to utilize radio resources of LTE and WLAN. LWIP can involve UE 210 using WLAN radio resources (e.g., connection interface 218) via IPsec protocol tunneling to authenticate and encrypt packets (e.g., Internet Protocol (IP) packets) communicated via connection interface 218. IPsec tunneling can include encapsulating the entirety of original IP packets and adding a new packet header, thereby protecting the original header of the IP packets.

RAN 220 can include one or more RAN nodes 222-1 and 222-2 (referred to collectively as RAN nodes 222, and individually as RAN node 222) that enable channels 214-1 and 214-2 to be established between UEs 210 and RAN 220. RAN nodes 222 can include network access points configured to provide radio baseband functions for data and/or voice connectivity between users and the network based on one or more of the communication technologies described herein (e.g., 2G, 3G, 4G, 5G, WiFi, etc.). As examples therefore, a RAN node can be an E-UTRAN Node B (e.g., an enhanced Node B, eNodeB, eNB, 4G base station, etc.), a next generation base station (e.g., a 5G base station, NR base station, next generation eNBs (gNB), etc.). RAN nodes 222 can include a roadside unit (RSU), a transmission reception point (TRxP or TRP), and one or more other types of ground stations (e.g., terrestrial access points). In some scenarios, RAN node 222 can be a dedicated physical device, such as a macrocell base station, and/or a low power (LP) base station for providing femtocells, picocells or the like having smaller coverage areas, smaller user capacity, or higher bandwidth compared to macrocells. A RAN node can generally be referred to herein as base station 222. Satellites 260 can operate as RAN nodes 222, with respect to UEs 210. As such, references herein to a base station, RAN node 222, etc., can involve implementations where the base station, RAN node 222, etc., is a terrestrial network (TN) node and also to implementation where the base station, RAN node 222, etc., is a NTN node (e.g., satellite 260).

Some or all of RAN nodes 222, or portions thereof, can be implemented as one or more software entities running on server computers as part of a virtual network, which can be referred to as a centralized RAN (CRAN) and/or a virtual baseband unit pool (vBBUP). In these implementations, the CRAN or vBBUP can implement a RAN function split, such as a packet data convergence protocol (PDCP) split wherein radio resource control (RRC) and PDCP layers can be operated by the CRAN/vBBUP and other Layer 2 (L2) protocol entities can be operated by individual RAN nodes 222; a media access control (MAC)/physical (PHY) layer split wherein RRC, PDCP, radio link control (RLC), and MAC layers can be operated by the CRAN/vBBUP and the PHY layer can be operated by individual RAN nodes 222; or a “lower PHY” split wherein RRC, PDCP, RLC, MAC layers and upper portions of the PHY layer can be operated by the CRAN/vBBUP and lower portions of the PHY layer can be operated by individual RAN nodes 222. This virtualized framework can allow freed-up processor cores of RAN nodes 222 to perform or execute other virtualized applications.

In some implementations, an individual RAN node 222 can represent individual gNB-distributed units (DUs) connected to a gNB-control unit (CU) via individual Fl or other interfaces. In such implementations, the gNB-DUs can include one or more remote radio heads or radio frequency (RF) front end modules (RFEMs), and the gNB-CU can be operated by a server (not shown) located in RAN 220 or by a server pool (e.g., a group of servers configured to share resources) in a similar manner as the CRAN/vBBUP. Additionally, or alternatively, one or more of RAN nodes 222 can be next generation eNBs (i.e., gNBs) that can provide evolved universal terrestrial radio access (E-UTRA) user plane and control plane protocol terminations toward UEs 210, and that can be connected to a 5G core network (5GC) 230 via an NG interface.

Any of the RAN nodes 222 can terminate an air interface protocol and can be the first point of contact for UEs 210. In some implementations, any of the RAN nodes 222 can fulfill various logical functions for the RAN 220 including, but not limited to, radio network controller (RNC) functions such as radio bearer management, uplink and downlink dynamic radio resource management and data packet scheduling, and mobility management. UEs 210 can be configured to communicate using orthogonal frequency-division multiplexing (OFDM) communication signals with each other or with any of the RAN nodes 222 over a multicarrier communication channel in accordance with various communication techniques, such as, but not limited to, an OFDMA communication technique (e.g., for downlink communications) or a single carrier frequency-division multiple access (SC-FDMA) communication technique (e.g., for uplink and ProSe or sidelink (SL) communications), although the scope of such implementations may not be limited in this regard. The OFDM signals can comprise a plurality of orthogonal subcarriers.

In some implementations, a downlink resource grid can be used for downlink transmissions from any of the RAN nodes 222 to UEs 210, and uplink transmissions can utilize similar techniques. The grid can be a time-frequency grid (e.g., a resource grid or time-frequency resource grid) that represents the physical resource for downlink in each slot. Such a time-frequency plane representation is a common practice for OFDM systems, which makes it intuitive for radio resource allocation. Each column and each row of the resource grid corresponds to one OFDM symbol and one OFDM subcarrier, respectively. The duration of the resource grid in the time domain corresponds to one slot in a radio frame. The smallest time-frequency unit in a resource grid is denoted as a resource element. Each resource grid comprises resource blocks, which describe the mapping of certain physical channels to resource elements (REs). Each resource block can comprise a collection of resource elements; in the frequency domain, this can represent the smallest quantity of resources that currently can be allocated. There are several different physical downlink channels that are conveyed using such resource blocks.

Further, RAN nodes 222 can be configured to wirelessly communicate with UEs 210, and/or one another, over a licensed medium (also referred to as the “licensed spectrum” and/or the “licensed band”), an unlicensed shared medium (also referred to as the “unlicensed spectrum” and/or the “unlicensed band”), or combination thereof. A licensed spectrum can correspond to channels or frequency bands selected, reserved, regulated, etc., for certain types of wireless activity (e.g., wireless telecommunication network activity), whereas an unlicensed spectrum can correspond to one or more frequency bands that are not restricted for certain types of wireless activity. Whether a particular frequency band corresponds to a licensed medium or an unlicensed medium can depend on one or more factors, such as frequency allocations determined by a public-sector organization (e.g., a government agency, regulatory body, etc.) or frequency allocations determined by a private-sector organization involved in developing wireless communication standards and protocols, etc.

To operate in the unlicensed spectrum, UEs 210 and the RAN nodes 222 can operate using stand-alone unlicensed operation, licensed assisted access (LAA), enhanced LAA (eLAA), and/or further eLAA (feLAA) mechanisms. In such implementations, UEs 210 and the RAN nodes 222 can perform one or more known medium-sensing operations or carrier-sensing operations in order to determine whether one or more channels in the unlicensed spectrum is unavailable or otherwise occupied prior to transmitting in the unlicensed spectrum. The medium/carrier sensing operations can be performed according to a listen-before-talk (LBT) protocol.

The PDSCH can carry user data and higher layer signaling to UEs 210. The physical downlink control channel (PDCCH) can carry information about the transport format and resource allocations related to the PDSCH channel, among other things. The PDCCH can also inform UEs 210 about the transport format, resource allocation, and hybrid automatic repeat request (HARQ) information related to the uplink shared channel. Typically, downlink scheduling (e.g., assigning control and shared channel resource blocks to UE 210 within a cell) can be performed at any of the RAN nodes 222 based on channel quality information fed back from any of UEs 210. The downlink resource assignment information can be sent on the PDCCH used for (e.g., assigned to) each of UEs 210.

One or more of the techniques described herein can enable UE 210 to dual steer across different 3GPP networks. The UE can register with a first 3GPP network for dual steering and indicate a capability for dual steering. The first 3GPP network can register the UE for dual steering and provide the UE with rules and policies for dual steering. The rules and policies can be based on preferences, capabilities, and network subscriptions of UE 210. UE 210 can reregister with a second 3GPP network and indicate a capability to dual steer. The first and second 3GPP networks can coordinate to associate the duel steering registrations of UE 210 at the first and second 3GPP networks. UE 210 can proceed to engage in traffic steering and network switching based on the dual steering rules and policies. Many other aspects and examples are also described herein. Many other aspects and examples are also described herein.

The RAN nodes 222 can be configured to communicate with one another via interface 223. In implementations where the system is an LTE system, interface 223 can be an X2 interface. In NR systems, interface 223 can be an Xn interface. The X2 interface can be defined between two or more RAN nodes 222 (e.g., two or more eNBs/gNBs or a combination thereof) that connect to evolved packet core (EPC) or CN 230, or between two eNBs connecting to an EPC. In some implementations, the X2 interface can include an X2 user plane interface (X2-U) and an X2 control plane interface (X2-C). The X2-U can provide flow control mechanisms for user data packets transferred over the X2 interface and can be used to communicate information about the delivery of user data between eNBs or gNBs. For example, the X2-U can provide specific sequence number information for user data transferred from a master eNB (MeNB) to a secondary eNB (SeNB); information about successful in sequence delivery of PDCP packet data units (PDUs) to a UE 210 from an SeNB for user data; information of PDCP PDUs that were not delivered to a UE 210; information about a current minimum desired buffer size at the SeNB for transmitting to the UE user data; and the like. The X2-C can provide intra-LTE access mobility functionality (e.g., including context transfers from source to target eNBs, user plane transport control, etc.), load management functionality, and inter-cell interference coordination functionality.

As shown, RAN 220 can be connected (e.g., communicatively coupled) to CN 230. CN 230 can comprise a plurality of network elements 232, which are configured to offer various data and telecommunications services to customers/subscribers (e.g., users of UEs 210) who are connected to the CN 230 via the RAN 220. In some implementations, CN 230 can include an evolved packet core (EPC), a 5G CN (5GC), and/or one or more additional or alternative types of CNs. The components of the CN 230 can be implemented in one physical node or separate physical nodes including components to read and execute instructions from a machine-readable or computer-readable medium (e.g., a non-transitory machine-readable storage medium). In some implementations, network function virtualization (NFV) can be utilized to virtualize any or all the above-described network node roles or functions via executable instructions stored in one or more computer-readable storage mediums (described in further detail below). A logical instantiation of the CN 230 can be referred to as a network slice, and a logical instantiation of a portion of the CN 230 can be referred to as a network sub-slice. Network function virtualization (NFV) architectures and infrastructures can be used to virtualize one or more network functions, alternatively performed by proprietary hardware, onto physical resources comprising a combination of industry-standard server hardware, storage hardware, or switches. In other words, NFV systems can be used to execute virtual or reconfigurable implementations of one or more EPC components/functions.

As shown, CN 230, application servers 240, and external networks 250 can be connected to one another via interfaces 234, 236, and 238, which can include IP network interfaces. Application servers 240 can include one or more server devices or network elements (e.g., virtual network functions (VNFs) offering applications that use IP bearer resources with CM 230 (e.g., universal mobile telecommunications system packet services (UMTS PS) domain, LTE PS data services, etc.). Application servers 240 can also, or alternatively, be configured to support one or more communication services (e.g., voice over IP (VoIP sessions, push-to-talk (PTT) sessions, group communication sessions, social networking services, etc.) for UEs 210 via the CN 230. Similarly, external networks 250 can include one or more of a variety of networks, including the Internet, thereby providing the mobile communication network and UEs 210 of the network access to a variety of additional services, information, interconnectivity, and other network features.

Satellites 260 can communicate with UEs 210 via service link or wireless interface 262 and/or RAN 220 via feeder links or wireless interfaces 264 (depicted individually as 264-1 and 264-2). In some implementations, satellite 260 can operate as a passive or transparent network relay node regarding communications between UE 210 and the terrestrial network (e.g., RAN 220). In some implementations, satellite 260 can operate as an active or regenerative network node such that satellite 260 can operate as a base station to UEs 210 (e.g., as a base station of RAN 220). In some implementations, satellites 260 can communicate with one another via a direct wireless interface (e.g., 266) or an indirect wireless interface (e.g., via RAN 220 using interfaces 264-1 and 264-2).

Additionally, or alternatively, satellite 260 can include a GEO satellite, LEO satellite, or another type of satellite. Satellite 260 can also, or alternatively pertain to one or more satellite systems or architectures, such as a global navigation satellite system (GNSS), global positioning system (GPS), global navigation satellite system (GLONASS), BeiDou navigation satellite system (BDS), etc. In some implementations, satellites 260 can operate as bases stations (e.g., RAN nodes 222) with respect to UEs 210. As such, references herein to a base station, RAN node 222, etc., can involve implementations where the base station, RAN node 222, etc., is a terrestrial network node and implementation, where the base station, RAN node 222, etc., is a non-terrestrial network node (e.g., satellite 260). As described herein, UE 210 and base station 222 can communicate with one another, via interface 214, to enable enhanced power saving techniques.

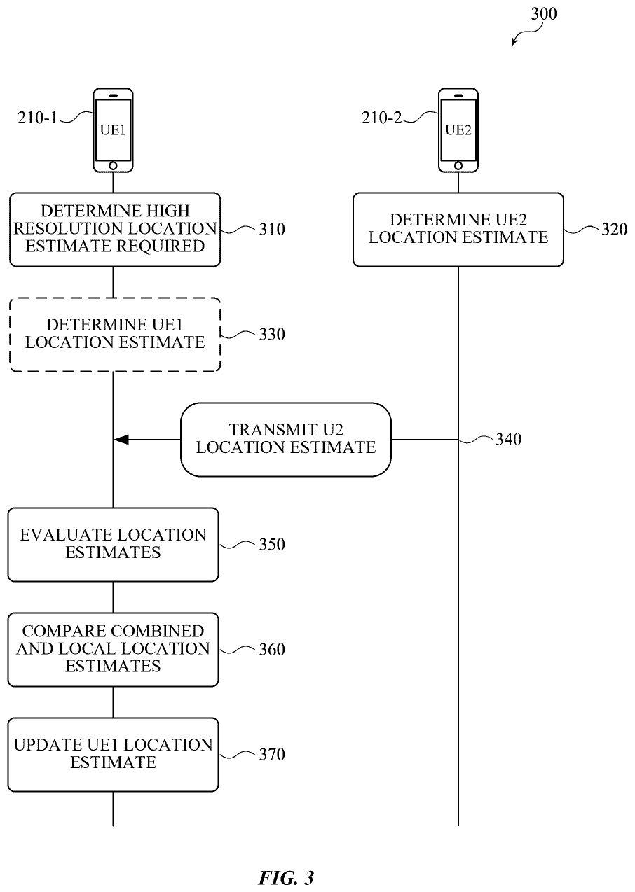

FIG. 3 is a diagram of an example process 300 for exchanging and updating location estimates according to one or more implementations described herein. As shown, process 300 can include UE 210-1 and UE 210-2. In some implementations, process 300 can include one or more fewer, additional, differently ordered and/or arranged operations than those shown in FIG. 3. In some implementations, some or all of the operations of process 300 can be performed independently, successively, simultaneously, etc., of one or more of the other operations of process 300. As such, the techniques described herein are not limited to a number, sequence, arrangement, timing, etc., of the operations or processes depicted in FIG. 3. As used herein, references to UE1 can correspond to UE 210-1, references to UE2 can correspond to UE 210-2, and so on.

Process 300 can include determining that a high-resolution estimate is required (at 310). In some scenarios, a first UE 210-1 can determine a need or detect a prompt, trigger, or conditions for a high-resolution, precise estimate of the location of the UE 210-1. For example, UE 210-1 can launch a software application that relies upon the precise location estimate to display a representation of a user's location overlaying a map, to hail a ride-sharing driver, send the location of UE 210-1 to a different device, etc. In response, UE 210-1 can prepare to determine and/or request an estimate of a current location of UE 210-1.

Process 300 can include UE 210-2 determining an estimate of a current location of UE 210-2 (at 320). In some scenarios, UE 210-2 can determine a location estimate of UE 210-2, autonomously and/or in response to a request to determine the location estimate from UE 210-1. In some scenarios, UE 210-2 can be in a group of UEs 210 that includes UE 210-1, such as when UE 210-1 and UE 210-2 are traveling together as described with reference to FIG. 1 (e.g., remaining within a distance threshold of one another, at a similar velocity, and along a similar trajectory). A group of UEs 210 can also be referred to herein as a UE group.

Process 300 can include UE 210-1 determining a location estimate of UE 210-1 (at 330). In some scenarios, the determination of the location estimate can share one or more of the operations and/or characteristics described with reference to the determination of the location estimate of UE 210-2 described above. In some scenarios, UE 210-1 can forgo determining a location estimate of UE 210-1 in anticipation of receiving a location estimate from UE 210-2, thus saving power that would otherwise be required to proactively determine the location estimate. In some implementations, a location estimate generated by a particular UE 210 can be referred to as a “local estimate” of the location of the UE 210. For example, the location estimate generated by UE 210-1 can be a local estimate of a current location of UE 210-1, as compared to a received location estimate from UE 210-2.

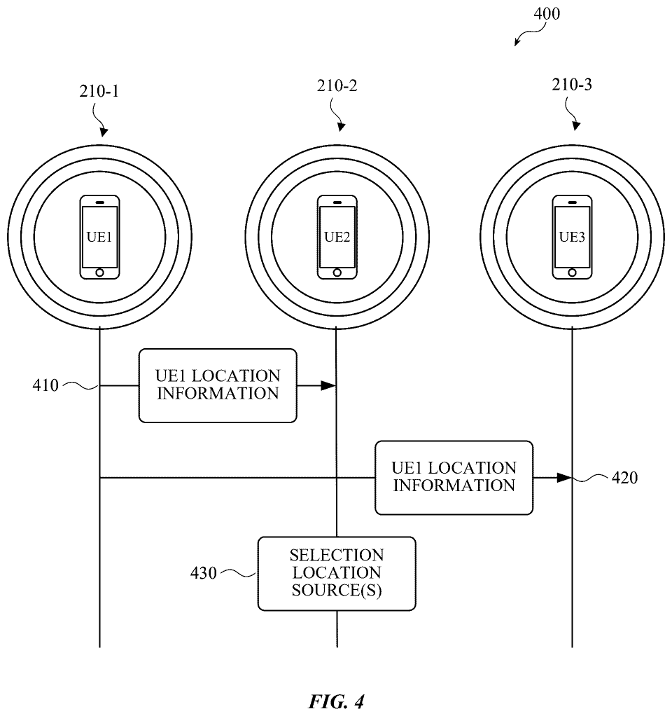

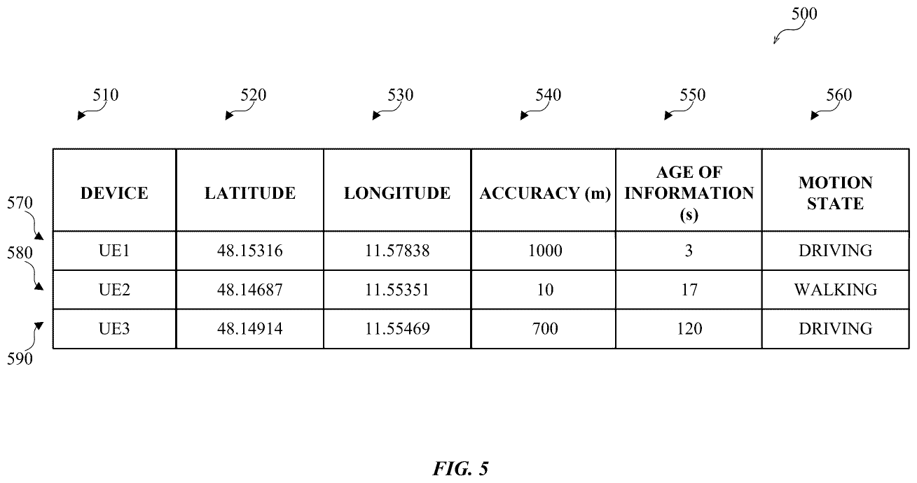

Process 300 can include UE 210-1 receiving a location estimate of UE 210-2 (at 340). The location estimate (as described further with reference to FIGS. 4 and 5) can be transmitted by UE 210-2 via SL or another type of D2D connection. For example, the location estimates and/or metadata defining characteristics of the location estimate can be transmitted between UEs 210 without relying upon an intermediary such as base station 222, a satellite [update with #when new FIG. 2 is included], or another type of wireless device. In some scenarios, the UE group can include UE 210-1, UE 210-2, and one or more additional UEs 210 (not shown). In such scenarios, UE 210-1 can receive additional or alternative location estimates from one or more of the other UEs 210 of the UE group.

While not shown, UE 210-1 can also receive additional location information from UE 210-2. For example, the location estimate can include geographic coordinates (e.g., a longitude and latitude) estimating a location of UE 210-1. The additional location information can include an estimated accuracy (e.g., a distance of a radius of uncertainty), a timestamp indicating when the location estimate was generated, a state of motion of UE 210-2 when the location estimate was generated, and more. UE 210-1 can receive additional location information from other UEs 210 of the UE group as well. The additional location information can be referred to herein as metadata about location information or a location estimate.

Process 300 can include UE 210-1 evaluating the received location estimates and/or the local estimate of UE 210-1 (at 350). For example, UE 210-1 can combine a location estimate and additional location information of UE 210-1 to a location estimate and additional location information of UE 210-2. In some scenarios, UE 210-1 can combine the location estimates and additional location information (as described with reference to at least FIG. 7) which can result in a location estimate with a region of uncertainty certainty that is smaller than a region of uncertainty of the constituent location estimates used to generate the combined estimate.

Process 300 can include UE 210-1 comparing the combined location estimate and additional location information a local location estimate (at 360). For example, UE 210-1 can compare the relative shape and/or size of the uncertainty region of the location estimate against the shape and/or size of the uncertainty region of the combined location estimate. In some scenarios, when the combined location estimate is more precise and/or accurate than the local location estimate, UE 210-1 can determine that the combined location estimate is more suited for applications and/or operations designed for high-resolution location estimates.

Process 300 can include UE 210-1 updating a location estimate of UE 210-1 (at 370). For example, UE 210-1 can update a location estimate of UE 210-1 to be the combined location estimate when the combined location estimate is determined to be more precise and/or accurate than the local location estimate. UE 210-1 can also provide the updated location estimate to an application or operation configured to use location estimates.

FIG. 4 is a diagram of an example process 400 for sharing location information between UEs 210 in a group of UEs 210 according to one or more implementations described herein. As shown, process 400 can include UE 210-1, UE 210-2, and UE 210-3. In some implementations, process 400 can include one or more fewer, additional, differently ordered and/or arranged operations than those shown in FIG. 4. In some implementations, some or all of the operations of process 400 can be performed independently, successively, simultaneously, etc., of one or more of the other operations of process 400. As such, the techniques described herein are not limited to a number, sequence, arrangement, timing, etc., of the operations or processes depicted in FIG. 4. As used herein, references to UE1 can correspond to UE 210-1, references to UE2 can correspond to UE 210-2, and so on.

As shown, process 400 can include UE 210-1 can transmitting location information and/or metadata describing the location information to other devices (at 410 and 420). The location information can include a location estimate and the metadata can include additional location information. In some scenarios, UE 210-1 can determine a high-resolution estimate of a current location of UE 210-1 and can share the estimate with UEs 210-2 and 210-3.

Process 400 can include UE 210-2 selecting a source of the location information and/or metadata from UE 210-1 (block 430). For example, UE 210-2 can receive the location information and/or metadata from UE 210-1 and evaluate the information to determine one or more characteristics of the information. Examples of such characteristics can include what type of location procedure or technology was used to generated the information (e.g., GNSS, cellular, WiFi®, etc.), whether the location estimate is as accurate, less accurate, or more accurate than a location estimate produced by UE 210-2 and/or another device of the UE group. Based on the characteristics, UE 210 can be configured to determine a value or accuracy of the received information, determine a source (e.g., a device) of the information, and select sources of location information determined to be valuable, accurate, or otherwise an enhancement of an ability of UE 210-2 to determine an accurate location estimate of UE 210-2. Examples for selecting sources of location information are described below with reference to FIGS. 6 and 7.

While not shown in FIG. 4, UEs 210-2 and 210-3 can be configured to determine lower resolution estimates than UE 210-1. The high-resolution estimate of UE 210-1 can consume a greater amount of power compared to the power consumption of the lower resolution estimates of UEs 210-2 and 210-3. In some implementations, UE 210-2 and 210-3 can use the location information from UE 210-1 instead of, and/or as a supplement to, a location estimate generated by UE 210-2 and 210-3. UE 210-2 and 210-3 can save power by using the location information from UE 210-1 instead of a location estimate generated by UE 210-2 and 210-3.

UEs 210-1 through 210-3 can periodically broadcast signals indicating their presence in a particular geographic area, thus providing opportunities for additional, and/or alternative, UEs to join the group. This can also enable UEs 210-1 through 210-3 to detect when one or more UEs 210 leaves the UE group. UE 210 can leave a UE group by moving beyond a threshold distance from UEs 210 of the UE group, having a measured D2D signal strength fall below a signal strength threshold, becoming part of another UE group, and more.

UEs 210-1, 210-2, and/or 210-3 can determine whether they are in a same group of devices. For example, one or more of UEs 210 can periodically transmit and/or receive signals that can be used to detect a presence and/or proximity of other UEs 210. A UE group can be formed, joined, left, disbanded, and/or modified based on a detected presence or proximity of UEs 210. UE 210 can determine presence and/or proximity based on one or more metrics or conditions relative to one or more corresponding thresholds. Examples of such metrics can include a measured signal strength, reference signal received power (RSRP), signal-to-noise ratio (SNR), received signal strength indicator (RSSI), etc. The metrics can also include one or more aspects of time, such as a UE 210 remaining proximate or non-proximate (as measured by an RSRP, SNR, etc.) to another UE 210 for at least a threshold period of time. In some scenarios, UEs 210-1 through 210-3 can determine they are in a same group when they are each in a same motion state, as described in further detail with respect to FIG. 5. For example, UEs 210-1 through 210-3 can be in a group when they are all stationary, are moving in a vehicle, and/or are walking.

In some scenarios, when UEs 210 are proximate (e.g., within a threshold distance) of one another for an amount of time greater than a threshold amount of time, UEs 210 can initiate the exchanging of location information as illustrated in FIG. 4. In some scenarios, UEs 210 can additionally, or alternatively, verify whether user accounts logged into respective UEs 210 belong to a group of user accounts sharing some common characteristics. For example, UEs 210 can determine that the corresponding user accounts are associated with the same paid subscription, such as a subscription for cloud services. In some scenarios, when UEs 210 do not belong to the same group of user accounts, UEs 210 can forgo transmitting or exchanging location information. Thus, UEs 210 can share location information when other devices are trusted and/or approved by virtue of belonging to a same group of user accounts. Additionally or alternatively, UEs 210 can admit other UEs into the group when the other UEs are enrolled in a list of contacts. For example, UE 210-1 can determine UE 210-2 is in a list of contacts at the UE 210-1 and/or UE 210-2 can determine UE 210-1 is in a list of contacts at UE 210-2, and can establish a group between the UEs 210-1 and 210-2. In such an example, if UE 210-3 is not included in the list of contacts at UE 210-1 and/or at UE 210-2, UE 210-3 can be excluded to the group.

One or more of UEs 210-1 through 210-3 can be programmatically configured with one or more state machines to facilitate the sharing of location information. For example, each UE 210 can be configured with a transmitting and a receiving state machine. The transmitting state machine can cause or enable UE 210 to determine whether other UEs 210 are nearby and/or included in a same UE group. When there are no nearby UEs 210, UE 210 can wait for a first period of time. When another UE 210 is nearby, UE 210 can check whether a location estimate has been received from the UE 210, and/or whether an accuracy of the received location estimate is greater than a threshold accuracy (e.g., a radius of uncertainty corresponding to the location estimate is less than a threshold radius). In some scenarios, when the received location estimate is not greater than the threshold accuracy, UE 210 can transmit its local estimate to the other UE(s) in the group. In some scenarios, when the received location estimate is greater than the threshold accuracy, UE 210 can wait for a second period of time, different from the first period of time, which can correspond to an expiration timer that dictates whether a location estimate is too old to reliably estimate the location of UE 210. In some scenarios, after UE 210 waits for the second period of time, UE 210 can again check whether there are nearby UEs 210 with which location information can be exchanged, potentially repeating one or more of the operations described above. In some scenarios, the value of the expiration timer is dependent upon a motion state associated with a location estimate. For example, UE 210-1 can receive a first location estimate from UE 210-2 and metadata indicating that UE 210-2 was walking when the first location estimate was generated, and can set a value of an expiration timer for the first location estimate to a first value. UE 210-1 can receive a second location estimate from UE 210-2 and metadata indicating that UE 210-2 was driving the second location estimate is determined, and can set a value of an expiration timer for the second location estimate to a second value, different from (e.g., less than or greater than) the first value.

FIG. 5 is a diagram of an example table 500 of location information according to one or more implementations described herein. Table 500 can include examples of location estimate information and additional location information (or metadata). In some implementations, location information can include fewer, additional, and/or alternative types of information than the information of table 500. As such, the techniques described herein are not limited to the type, quantity, or arrangement of information depicted in FIG. 5. As shown, table 500 can include locally determined location information of UEs 210 of a UE group, which can be exchanged between UEs 210 in the UE group. For example, table 500 includes rows 570 through 590, which respectively correspond to a first UE (UE1), a second UE (UE2), and a third UE (UE3). Table 500 further includes columns that each correspond to a type of information included in the location information and/or location metadata. For example, columns 520 and 530 correspond to latitude and longitude, respectively. Column 540 corresponds to an accuracy of the latitude and longitude estimate, which can correspond to a typical, determined, or specified value and unit type associated with a particular sensing modality used to generate the latitude and/or longitude. In some scenarios, the accuracy can additionally or alternatively be determined in accordance with detected aspects of the physical environment, characteristics of circuitry of UE 210 (e.g., localization circuitry, radio frequency circuitry, antenna configurations, power mode of UE 210, and/or a combination thereof), and/or characteristics of signals measured by UE 210, which can be indicative of a power, quality, and/or signal interference associated with signals received by UE 210 and/or transmitted by UE 210 (e.g., to entities external to the UE group, such as base station 222, satellite 260, and/or a localization beacon).

Table 500 further includes column 550, which includes an “age” of the information. The age of information can include a difference between a time that a particular location estimate is generated with a current time detected at UE 210, thus indicating how much time has elapsed since the location estimate was generated. Table 500 further includes column 560, which indicates a “motion state” of UE 210 when the location estimate is generate. A motion state can refer to a qualitative assessment of a movement, acceleration, or velocity of UE 210. A motion state can indicate whether a user of UE 210 is stationary, walking, running, driving, moving in public transit, and/or the like, when a particular location estimate is generated.

In FIG. 5, the first, second, and third UEs are included in a group of UEs, as described further above, and can exchange their respective location estimates. As indicated in row 570, the first UE can have a latitude and longitude that is similar to the second and the third UE but can have a relatively low degree of confidence due to the relatively large (e.g., 1000 meters (m)) accuracy radius as indicated in column 540. Thus, given the state of motion of the first UE being that of driving, without using a combined location estimate, the first UE may not have a granular fix on location of the first UE. As indicated by row 580 and column 540, the second UE can have a higher accuracy estimate of its location (e.g., the accuracy radius is 10m). Accordingly, the second UE can share a location estimate of the second UE with the first UE, and the first UE can combine its local but broad location estimate with the relatively more precise estimation from the second UE to reduce uncertainty and improve accuracy of its geolocation.

The third UE (indicated by row 590 and column 540) can also a relatively inaccurate local location estimate, which can be supplemented by the location estimate received from the second UE in a manner similar to the example described above with reference to the first UE. The local location estimate of the third UE, as indicated by column 550, can also be relatively old (e.g., 120 seconds(s)). Thus, the third UE can further benefit from the recency of the location estimate received from the first UE in light of the age of the local location estimate of the third UE. As indicated in column 560, the first and the third UE can be in rapid motion, which when detected by the UEs, can cause the UEs to determine they are in a driving motion state. In some scenarios, the UEs can detect their speed and/or direction and can extrapolate an estimated location based on the age of information included in column 550.

FIG. 6 is a diagram of an example process 600 for selecting a location estimate source according to one or more implementations described herein. Process 600 can be implemented by UE 210. In some implementations, some or all of process 600 can be performed by one or more other systems or devices, including one or more of the devices of FIG. 2. Additionally, process 600 can include one or more fewer, additional, differently ordered and/or arranged operations than those shown in FIG. 6. In some implementations, some or all of the operations of process 600 can be performed independently, successively, simultaneously, etc., of one or more of the other operations of process 600. As such, the techniques described herein are not limited to a number, sequence, arrangement, timing, etc., of the operations or processes depicted in FIG. 6.

Process 600 can include determining that UE 210 is part of a group (at 610). For example, UE 210 can periodically broadcast one or more signals and can detect whether similar signals have been broadcast by one or more other devices or UEs 210. In response to receiving such signals, UE 210 can determine that other UEs 210 are proximate, and potentially traveling together. In response to receiving such signals over a period of time, UE 210 can determine that UE 210 is geolocated in similar or the same locations as the other UEs 210. Additionally or alternatively, UE 210 can determine that one or more criteria with respect to characteristics of the received signals are satisfied, such as a criterion satisfied when a RSSI of the received signal is greater than a threshold RSSI, a criterion satisfied when a SNR is greater than a threshold SNR, and/or a criterion that is satisfied when the signal is received within a threshold period of time from an instant of time (e.g., a start time of a polling period and/or a time at which other UEs are added to the group of UEs 210), and/or some combination thereof. When the one or more criteria are satisfied, when the one or more criteria continue to be satisfied over a period of time, and/or when one or more instances of received signals consecutively satisfy the one or more criteria, UE 210 can determine that UE 210 is moving with a UE group of other devices and/or UEs 210.

In some scenarios, a first communication protocol used to transmit and/or receive location estimates to UEs 210. The first communication protocol can be the same as or different from a second communication protocol used to broadcast the presence and/or proximity of the UE 210 when establishing a group of UEs 210. For example, UE 210-1 can transmit first signals advertising a presence and/or proximity to other UEs 210 using a first D2D protocol, such as Bluetooth®, and can transmit second signals using a second D2D protocol, such as a D2D mesh protocol, SL, or using Bluetooth®. In some scenarios, UE 210-1 can continue to broadcast the signals used to indicate presence and/or proximity while performing one or more of the operations of process 600, thus continuing to search for new UEs 210 to connect with, to add and/or remove UEs 210 from the UE group, etc.

Process 600 can include determining whether a local estimate is available (at 620). In some scenarios, UE 210 can determine a location estimate. For example, UE 210-1 can connect to a first base station 222 indicating that UE 210-1 is located within a first geographic region, or can connect to a second base station 222 indicating that UE 210-1 is located within a second geographic region. Additionally or alternatively, UE 210-1 can have previously determined and/or received an indication of a current location of UE 210-1 via GNSS, thus giving UE 210-1 a high-quality location estimate. Additionally or alternatively, UE 210-1 can have a location estimate that has been previously provided by another UE 210 of the group, and/or UE 210-1 can have a location estimate that was provided from a UE group with which UE 210 was previously traveling. Additionally or alternatively, UE 210-1 can have a location estimate that is based upon a combination of multipole location estimates (e.g., at 690). When a local estimate is not available (620—NO), process 600 can include configuring UE 210 to receive location estimates (at 630). For example, UE 210-1 can configure transceivers of UE 210-1 to receive location information from other UEs 210 of the UE group.

When a local estimate is available (620—YES), process 600 can include determining that the local estimate satisfies one or more criteria (at 640). For example, UE 210-1 can determine whether an accuracy of the local estimate is less than or equal to a threshold level of accuracy. Location estimates can be associated with a level of accuracy that is based on a type of geolocation technology used to generate the location estimate. The threshold level of accuracy, therefore, can correspond to a threshold distance of the accuracy. In some scenarios, the accuracy of the location estimate can be used to determine or generate a region of uncertainty associated with a location estimate. For example, the region of uncertainty can be circular, having a center corresponding to the coordinates that correspond to the location estimate and a radius of uncertainty corresponding to the accuracy of the location estimate. When the radius is less than a threshold radius, the location estimate can satisfy the one or more criteria. When greater than the threshold radius, the location estimate may not satisfy the one or more criteria.

Additionally or alternatively, the region of uncertainty can be elliptical, rectangular, or some asymmetrical shape. For example, UE 210-1 can determine that the UE 210-1 is unlikely to be located in a body of water while previously driving and can modify the region of uncertainty that otherwise could be circular by removing portions of the region that correspond to the body of water from the region of uncertainty. When an area included in the region of uncertainty is greater than a threshold area, the location estimate can satisfy the one or more criteria. When the area is less than the threshold area, the location estimate may not satisfy the one or more criteria. It is therefore understood that description of regions of uncertainty presented herein can correspond to a region that defines an accuracy of a location estimate. When the local estimate satisfies the one or more criteria (at 640—YES), process 600 can include configuring the UE to transmit location estimates (at 650). For example, UE 210-1 can configure transceivers included in UE 210-1 to transmit location estimates to other UEs 210 in the group of UEs 210.

When the local estimate does not satisfy the one or more criteria (at 640—NO), process 600 can include determining whether a high-quality local estimate is required (at 670). For example, UE 210-1 can determine whether a software application run at UE 210-1 and/or a software application run by another UE 210 in the UE group will use (or is using) a high-quality location estimate. Such software applications can include those that rely upon location data, such as mapping applications, traffic applications, software applications that check location data to surface relevant content to the user, emergency localization applications, astronomy applications, and/or the like. UE 210-1 can determine that the software application is running and/or has requested a high-quality location estimate and can therefore determine that the high-quality estimate is required. Additionally or alternatively, UE 210-1 can transmit and/or receive an indication that the high-quality location estimate is required by other UEs 210 in the UE group. Based on receiving such an indication from another UE in the group, UE 210-1 can additionally or alternatively determine that such a high-quality location estimate is required and can initiating one or more operations to obtain the high-quality location estimate to supplement the localization efforts of the other UE(s) 210.

Additionally or alternatively, the UE 210-1 can receive the indication that the high-quality estimate is required, and based upon a determination that UE 210-1 is in a less-than-ideal operating configuration to provide the location estimate (e.g., battery level is less than a threshold level, CPU usage is greater than a threshold level of usage, and/or the UE 210-1 is configured in a particular operating mode such as a low-power consumption mode), the UE 210-1 can forgo transmitting and/or can proceed with receiving of a high-quality location estimate. When the high-quality location is required or preferred, process 600 can include configuring the UE to receive the location estimates as described above (e.g., at 630). When the high quality estimate is not required, process 600 can include forgoing receiving of a location estimate (at 680). Additionally or alternatively, process 600 can include forgoing the configuring of UE 210 to receive the location estimate.

Process 600 can include exchanging location estimates with devices included in a group of devices (at 660). For example, UE 210-1 can transmit and/or receive based upon whether the local estimate satisfied the one or more criteria (at 640) and/or whether the local estimate was available (at 630). Accordingly, the UE 210-1 can transmit and/or receive location estimate(s) to other UEs 210 in the UE group. As described further herein, the transmitting and/or receiving of the location estimate can include location information and/or metadata describing the location information as described above with reference to FIG. 5.

Process 600 can include combining location estimates (at 690). For example, UE 210-1 can combine location estimates as described with reference to FIG. 3. In some scenarios, combining location estimates can include modifying the accuracy of the measurement based upon one or more of an age of information, a motion state, a speed, and/or a direction of the UE 210-1 that generated the location estimate. For example, the combining process can include determining a speed of the UE 210-1 based upon measured speed and/or based upon the motion state of UE 210-1. A particular motion state can be associated with a corresponding maximum speed, such as a stationary, or near stationary velocity (e.g., 0 to 0.5 meters per second (m/s)), a walking velocity (e.g., 0.5 to 1.5 m/s), a running velocity (e.g., 1.5 to 5 m/s), and/or a driving velocity (e.g., greater than 5 m/s). In some scenarios, the velocity of UE 210-1 can be a predetermined value that falls within a range of velocities for each motion state. For example, the velocity of UE 210-1 can correspond to 1.5 m/s when the UE 210-1 motion state corresponds to a walking motion state.

In some scenarios, based upon the motion state and/or velocity, UE 210-1 can determine a radius of uncertainty and/or accuracy caused by the movement of the UE 210-1 over a period of time. The radius of uncertainty can be referred to herein as a movement radius. For example, UE 210-1 can multiply and/or otherwise scale the speed (e.g., the measured speed and/or the speed corresponding to a particular motion state) of UE 210-1 by the age of information. As described above, the age of information can correspond to how much time has elapsed from when the location information is detected and/or generated by a particular UE 210. Thus, the scaling of the speed by the age of information can yield a distance that corresponds to an additional distance of uncertainty and/or accuracy associated with location estimates, accounting for distance that a UE 210 potentially traveled since providing a location estimate. In some scenarios, UE 210-1 can combine the movement radius with the distance that corresponds to the accuracy of the location estimate (e.g., the accuracy distance being based upon a type of sensing technology, the physical environment around of UE 210, and/or more). For example UE 210-1 can add the movement radius to the accuracy of the location estimate to determine a measurement radius indicative of a degree of uncertainty of a location estimate, thus optionally defining an uncertainty region around a location estimate. In some scenarios, the UE 210-1 can scale the factors used to generate the measurement radius, such as weighing the measurement radius to have a relatively smaller effect on determining the size of the measurement radius or weighing the measurement radius to have a relatively greater effect on determining the size of the measurement radius. Thus, UE 210-1 can be capable of accounting for motion away from a particular location estimate, without the device that detected the location estimate refresh the location estimate and/or transmit an additional location estimate.

In some scenarios, UE 210 can change the measurement radius based upon a distance between UEs 210. For example, when assessing and/or weighing the contribution of a received location estimate from UE 210-2, UE 210-1 can determine and/or obtain a distance between UE 210-1 and UE 210-2 when a location estimate is received from UE 210-2, and/or a distance between the UEs when the location estimate is generated by UE 210-2. In some scenarios, UE 210-1 can add the distance between the UEs 210 to the measurement radius. In some scenarios, the distance can correspond to a measured and/or determined distance, such as a distance determined by detecting a time-of-flight of signals transmitted between UEs 210-1 and 210-2. In some scenarios, the distance can correspond to a predetermined distance, such as a maximum or nominal range of a communication technology such as Bluetooth® that UEs 210-1 and 210-2 are using to communicate location information. In some scenarios, local estimates are not modified by some inter-device distance, because the local estimates are determined by the UE 210 that is performing the combining of location estimates.

In some scenarios, UE 210 can determine a region of uncertainty based on some combination of one or more of the radii or distances described above and can determine a region of intersection between the regions of uncertainty. For example, UE 210 can sum the values of the applicable radii and/or accuracy, determining a region of uncertainty that is centered on the location estimate and that has a boundary that corresponds to the summed radii. The regions of uncertainty, therefore, can define regions of the physical environment that each UE 210 is determined to be within.

In some scenarios, UE 210-1 scan determine an intersection between a multiple regions of uncertainty and can improve accuracy and quality of a location estimate based upon the intersection. For example, when a local estimate generated by UE 210-1 is centered on a first location with a 1 kilometer (km) boundary in a first region of uncertainty, and a received estimate from UE 210-2 is centered on a second location with a 15 m boundary in a second region of uncertainty, the intersection between the first and the second regions of uncertainty can be more precise, and therefore used to produce a higher-quality location estimate for UE 210-1. It is understood that the intersecting region of uncertainty can be based upon multiple location estimates from multiple UEs 210 in a UE group. Thus, due to differences in size of the regions of uncertainty used to determine a combined location estimate, the uncertainty region of the combined location estimate can be a first shape and/or size, a second shape and/or size, a third shape and/or size, etc.

The higher-quality location estimate can be used by UE 210-1 to update an internal location estimate of UE 210-1, thus providing the appropriate software application that requires a location estimate with a geolocation fix that is potentially more accurate than the local location estimate. By accounting for estimate uncertainty in accordance with the location information metadata (e.g., age of information, UE speed, measurement accuracy, etc.), UE 210-1 can be able to determine location estimates that can potentially be highly accurate based upon a combination of a plurality of location estimates, and can reduce power consumption used to request that contributing UEs 210 can collect additional location estimates that are relatively older.

In some scenarios, some or all of the above-described operations can be repeated over time. For example, UE 210-1 can determine a combined estimate and/or share the local location estimate a first time while included in a group of UEs 210 including a first set of

UEs. UE 210-2 can subsequently detect that one or more of the first set of UEs 210 has left the UE group, and/or that one or more additional UEs 210 has join the UE group. Based upon the exiting and/or entering of one or more UEs 210 to the UE group, UE 210-1 can repeat one or more of the above-described operations. For example, UE 210-1 can delay determination of a combined location estimate when a new UE 210 joins the UE group and can determine the combined location estimate after receiving a location estimate from the new UE 210. Additionally or alternatively, UE 210-1 can forgo updating its location estimate until the new location estimate is received from the new UE 210.

FIG. 7 is a diagram of an example process 700 for selecting a location estimate source according to one or more implementations described herein. Process 700 can be implemented by UE 210. In some implementations, some or all of process 700 can be performed by one or more other systems or devices, including one or more of the devices of FIG. 2. Additionally, process 700 can include one or more fewer, additional, differently ordered and/or arranged operations than those shown in FIG. 7. In some implementations, some or all of the operations of process 700 can be performed independently, successively, simultaneously, etc., of one or more of the other operations of process 700. As such, the techniques described herein are not limited to a number, sequence, arrangement, timing, etc., of the operations or processes depicted in FIG. 7.

Process 700 can include comparing local and combined location estimates (at 710). For example, as described with reference to FIG. 6, UE 210-1 can compare an accuracy and/or size of a region of uncertainty of the local estimate against a combined location estimate. The comparison can include determining, between the local and combined location estimates, which radius of accuracy is smaller, which of an area of the regions of uncertainties is smaller, etc.

Process 700 can include determining whether the combined location estimate is higher quality and/or higher accuracy than the local location estimate (at 720). For example, UE 210-1 can determine that the combined location estimate has a size and/or a radius of accuracy and/or uncertainty that is smaller than a size and/or radius of accuracy of the local estimate. Additionally or alternatively, UE 210-1 can determine that the age of one or more of the location estimates (e.g., the local and/or constituent estimates included in the combined location estimate) is less than a threshold age; that the base accuracy of a location estimate (e.g., without adjusting by UE 210-1) is greater than a threshold accuracy; and/or that the motion states associated with location estimates correspond to a first set of motion states. When the combined location estimate is of lower quality and/or accuracy (at 720—NO), process 700 can include discarding the combined location estimate (at 715). For example, UE 210-1 can forgo updating a location estimate based upon the combined location estimate due to the location estimate of UE 210-1 having greater accuracy. When the combined estimate is of higher quality and/or accuracy (at 720—YES), process 700 can include updating the location estimate to be the combined estimate (at 725)

When the combined estimate is higher quality and/or higher accuracy than the local estimate (at 720—YES), process 700 can include determining whether UE 210 supports GNSS (at 730). When UE 210 does not support GNSS (at 730—NO), process 700 can include discontinuing some or all operations included in process 700 (at 760). For example, UE 210-1 can determine that an operating condition of UE 210-1, such as a power mode, a level of battery, a CPU usage, a thermal state, and so on. UE 210-1 can forgo performing additional or alternative operations included in process 700 (at least temporarily) when the power mode is a low power mode, the battery level is less than a threshold battery level, the CPU usage exceeds a threshold percentage usage, when the operating temperature exceeds a threshold temperature, and/or some combination thereof. Doing so can, for example, reduce power consumption of UE 210-1. By contrast, when one or more of conditions are satisfied and/or UE 210-1 includes circuitry to perform a GNSS scan, support for GNSS can be indicated.

When UE 210 supports GNSS (at 730—YES), process 700 can include determining whether the combined location estimate satisfies one or more criteria (at 740). For example, the one or more criteria can be satisfied when: an accuracy radius of the estimate is less than a threshold level, an age of one or more location estimates is less than a threshold age, an area of a region of uncertainty bounded by the accuracy radius is less than a threshold area, a number of location estimates used to generate the combined location estimate is greater than a threshold number, and/or one or more other types of conditions or characteristics satisfy a corresponding threshold. The satisfaction of the one or more criteria can at least in part define a level of quality of a location estimate.

When the combined location estimate satisfies the one or more criteria (at 740—YES), process 700 can include determining whether a GNSS scan is scheduled (at 770). When a GNSS scan is not scheduled (at 770—NO), process 700 can include discontinuing some or all operations included in process 700 (at 760). When a GNSS scan is scheduled (at 770—YES), process 700 can include canceling the scheduled GNSS scan (at 790). For example, UE 210-1 can cancel an upcoming GNSS scan because the combined location estimate is of sufficient quality such that UE 210-1 may not immediately require a GNSS location be obtained by UE 210-1, thereby saving power consumption by UE 210-1.

When the combined location estimate does not satisfy the one or more criteria (at 740—NO), process 700 can include determining whether a high-quality location estimate is required (at 750). For example, UE 210-1 can determine that a software application running at UE 210-1 and/or at other UEs 210 in the UE group can require or prefer the high-quality location estimate, as described with reference to FIG. 6, for example. When the high-quality location estimate is not required (at 750—NO), process 700 can include discontinuing some or all of the operations included in process 700 (at 760). For example, UE 210-1 can preemptively determine whether a high quality location estimate is required by a mapping application, and when not required or preferred, can forgo determining of a high quality location estimate, thus saving power.

When the high-quality location is required (at 740—YES), process 700 can include determining whether a scan for a location has been performed at a time that is within a threshold period of time (at 780). When the scan has been performed at a time that is within the threshold period of time (at 780—YES), process 700 can include discontinuing some or all of the operations included in process 700 (at 760). For example UE 210-1 can determine that a GNSS scan has recently been performed and can forgo performing some or all operations included in process 700, such as the operation of obtaining a GNSS scan.

When the scan has not been performed at a time that is within the threshold period of time, (at 780—NO), process 700 can include determining the UE location locally (at 792). For example, UE 210-1 can determine whether a GNSS scan has or has not been performed within the period of time. When the scan has not recently been performed, UE 210-1 can prepare for and/or initiate a scan for a GNSS location, to update the local location estimate and anchor additional combinations of the location estimate with other location estimates from other UEs 210. When the scan has recently been performed, UE 210-1 can forgo performing the scan, thus saving computational resources and power consumption of UE 210-1.

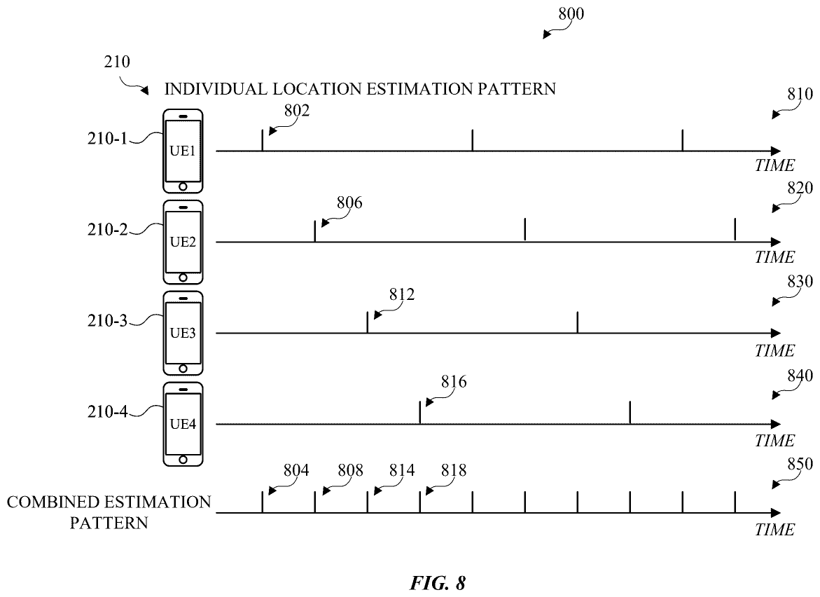

FIG. 8 is a diagram of an example of a group of UEs coordinating collection and sharing of location information according to one or more implementations described herein. For example, plots 800 includes a plurality of UEs 210 including UE 210-1, UE 210-2, UE 210-3, and UE 210-4 collecting and/or sharing location information at times indicated by plot 810, plot 820, plot 830, and plot 840, respectively. In some scenarios, UEs 210 can form a group of UEs 210 based on one or more of the operations described above and can coordinate times at which UEs 210 individually detect or estimate locations and/or share location information with other UEs 210 of the UE group. For example, UE 210-1 can first determine location estimate 802, and can share location estimate 802 with the UE group, as indicated by the location estimate 804 included in plot 850. Plot 850 can include an example of the effective timing of a combination of location information obtained by UEs 210 of the UE group. For example, location estimate 802 can be shared by UE 210-1, at the time corresponding to location estimate 804. Thus, although UE 210-2 may not have obtained a location estimate at a time corresponding to location estimate 802, UE 210-2 can have a high-quality location estimate (e.g., a GNSS location estimate) provided by UE 210-1, indicated by location estimate 804. Thus, from the perspective of each UE 210 in the group, a rapid sequence of location estimates can be available to each UE 210. Such an arrangement can thus reduce power consumption otherwise involved in an individual UE 210 determining location estimates at the rate depicted by plot 850, distributing the computational and power consumption requirements across the group of UEs 210 and/or improving the quality of location estimates available to each UE 210 in the UE group.

Similarly to as described above, UE 210-2 can determine location estimate 806 and can share that location estimate with the group, indicated by location estimate 808. UE 210-3 can determine location estimate 812 and can share that location estimate with the group, indicated by location estimate 814. UE 210-4 can determine location estimate 816 and can share that location estimate with the group, indicated by location estimate 818. Thus, although plots 810 through 840 indicate the individual location estimate determination pattern, plot 850 can indicate the effective location estimate pattern available at each of the UEs.

In some scenarios, UEs 210 can be configured to proactively determine a GNSS location irrespective of whether a high-quality location estimate is expressly required by a particular software application. In some scenarios, the negotiation and/or configuration of UEs 210 in the group is collaborative. For example, UEs 210 in a UE group can be configured based upon UE configurations and/or UE capabilities to detect a GNSS location with a specified periodicity (e.g., every one, two, three, four, five, seven, or ten minutes). In some scenarios, when UEs 210 determine that they are traveling and/or belong to a UE group, UEs 210 can distribute the times at which they respectively determine a location estimate to conserve power at each UE 210, as described above. In some scenarios, UEs 210 can synchronize a periodicity of the detecting of location estimates. For example, the UEs 210 can negotiate which UEs 210 are to most frequently or least frequently detect location information proactively. UEs 210 can thereafter configure the periodicity for individual location estimate schedules in accordance with a greatest or least periodicity. Additionally or alternatively, UEs 210 can negotiate a time offset and/or the periodicity such that the effective, combined location estimates illustrated in plot 850 corresponds to a target periodicity.

In some scenarios, the negation and/or configuration of UEs 210 in the UE group can be determined and/or driven by a lead device. For example, a lead device (or lead UE 210) can be a device such as one of UEs 210 that determines a hierarchy of devices and/or a sequence at which each of the device detect and/or share location estimates. Additionally or alternatively, the lead device can be a device that detects location information on behalf of the remaining devices in the group (e.g., detects location estimates in accordance with plot 850, while other UEs 210 in the group less frequently or entirely forgo detection of location estimates). In some scenarios, the lead device can have a high-quality location estimate that was previously detected and can be shared with other devices. For example, the lead device can be one of UEs 210 that is generating high-resolution location estimates as requested by software being executed at the UE 210-1, such as by a mapping application. In this example, the high-resolution location estimates can be generated before, during, and/or after the UE 210-1 joins the UE group including UEs 210. In some scenarios, UE 210-1 can continue to determine high-resolution location estimates on behalf of other UEs 210 in the UE group.

In some scenarios, the lead device corresponds to a device that satisfies one or more criteria. For example, the lead device can include circuitry and/or a configuration such as processing power and/or processing availability that exceeds the processing power and/or availability (e.g., CPU usage) of other devices. Additionally or alternatively, the one or more criteria can include a criterion that is satisfied when a battery level of the lead device is greater than or equal to a threshold level, a criterion that is satisfied when the battery level is greater than or equal to other battery levels of other devices in the group, a criterion that is satisfied when the charging state of the lead device is a particular charging state (e.g., is connected to a wired charger, connected to a wireless charger, and/or the like), a criterion that is satisfied when a thermal operating temperature of the device is less than a threshold temperature, a criterion that is satisfied when the thermal operating temperature is at a relative position within a range of operating temperatures, and/or some combination thereof.

In some scenarios, the lead device can determine the location estimate pattern, sequence, and/or arrangement of other devices in the UE group. For example, the lead UE can detect the operating configurations of the other devices, such as a periodicity of location estimation operations, a charge state, a battery level, an operating temperature, a requirement for high-quality location estimates, an antenna configuration, the accuracy of other location estimates that the individual devices have recently provided, and/or some combination thereof. In some scenarios, the lead UE can determine individual or shared configurations of periodicity of the proactive location estimate detection, how many consecutive location estimates that individual devices share with the group, whether certain devices will at least temporarily forgo detecting location estimates, the types of sensing technologies that the devices will use to determine a location estimate, etc.

In some scenarios, the lead UE 210 can determine or detect when UEs 210 of the UE group are added to and/or removed from the UE group. For example, UE 210-1 can be responsible for sensing whether one or more devices included in the UE group have moved beyond a threshold distance from the UE group and/or that one or more devices have moved within the threshold distance of the group. Accordingly, UE 210-2 through 210-4 can forgo detection and/or monitoring of the member devices included in the group and can collaborate with the devices indicated by UE 210-1 as included in the group. Additionally or alternatively, UE 210-1 can transmit requests for pairs of UEs to transmit indications of distance between the pairs of the UEs, and/or can schedule the transmitting of such requests, such that the pairs of UEs periodically send distance information germane to determining uncertainty of received location estimates.

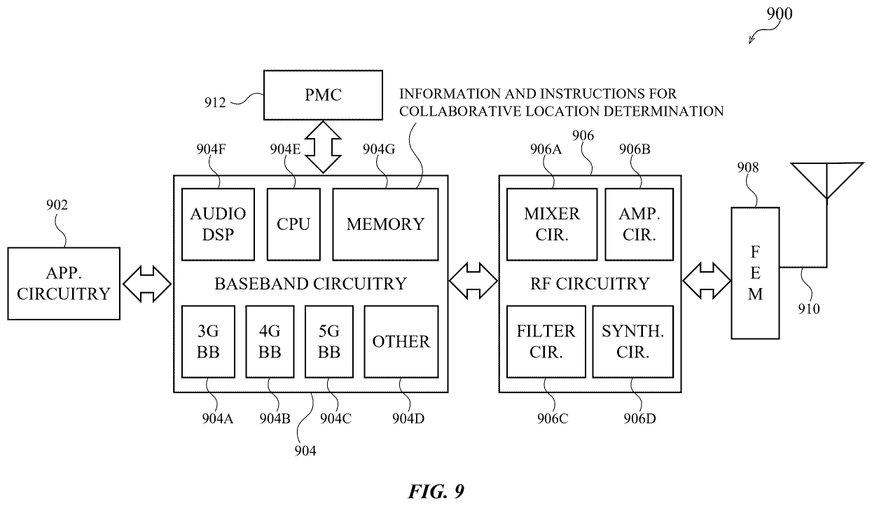

FIG. 9 is a diagram of an example of components of a device according to one or more implementations described herein. In some implementations, the device 900 can include application circuitry 902, baseband circuitry 904, RF circuitry 906, front-end module (FEM) circuitry 908, one or more antennas 910, and power management circuitry (PMC) 912 coupled together at least as shown. The components of the illustrated device 900 can be included in a UE or a RAN node. In some implementations, the device 900 can include fewer elements (e.g., a RAN node may not utilize application circuitry 902, and instead include a processor/controller to process IP data received from a CN or an Evolved Packet Core (EPC)). In some implementations, the device 900 can include additional elements such as, for example, memory/storage, display, camera, sensor (including one or more temperature sensors, such as a single temperature sensor, a plurality of temperature sensors at different locations in device 900, etc.), or input/output (I/O) interface. In other implementations, the components described below can be included in more than one device (e.g., said circuitries can be separately included in more than one device for Cloud-RAN (C-RAN) implementations).

The application circuitry 902 can include one or more application processors. For example, the application circuitry 902 can include circuitry such as, but not limited to, one or more single-core or multi-core processors. The processor(s) can include any combination of general-purpose processors and dedicated processors (e.g., graphics processors, application processors, etc.). The processors can be coupled with or can include memory/storage and can be configured to execute instructions stored in the memory/storage to enable various applications or operating systems to run on the device 900. In some implementations, processors of application circuitry 902 can process IP data packets received from an EPC.

The baseband circuitry 904 can include circuitry such as, but not limited to, one or more single-core or multi-core processors. The baseband circuitry 904 can include one or more baseband processors or control logic to process baseband signals received from a receive signal path of the RF circuitry 906 and to generate baseband signals for a transmit signal path of the RF circuitry 906. Baseband circuitry 904 can interface with the application circuitry 902 for generation and processing of the baseband signals and for controlling operations of the RF circuitry 906. For example, in some implementations, the baseband circuitry 904 can include a 3G baseband processor 904A, a 4G baseband processor 904B, a 5G baseband processor 904C, or other baseband processor(s) 904D for other existing generations, generations in development or to be developed in the future (e.g., 5G, 6G, etc.). The baseband circuitry 904 (e.g., one or more of baseband processors 904A-D) can handle various radio control functions that enable communication with one or more radio networks via the RF circuitry 906. In other implementations, some or all of the functionality of baseband processors 904A-D can be included in modules stored in the memory 904G and executed via a Central Processing Unit (CPU) 904E. The radio control functions can include, but are not limited to, signal modulation/demodulation, encoding/decoding, radio frequency shifting, etc. In some implementations, modulation/demodulation circuitry of the baseband circuitry 904 can include Fast-Fourier Transform (FFT), precoding, or constellation mapping/de-mapping functionality. In some implementations, encoding/decoding circuitry of the baseband circuitry 904 can include convolution, tail-biting convolution, turbo, Viterbi, or Low-Density Parity Check (LDPC) encoder/decoder functionality. Implementations of modulation/demodulation and encoder/decoder functionality are not limited to these examples and can include other suitable functionality in other implementations.

In some implementations, memory 904G can receive and store one or more configurations, instructions, and/or other types of information to enable collaborative estimation of UE location. When the UE is determined to be moving with other UEs, the UEs can form a group. The UEs can determine their location collaboratively, based on location information and/or location information metadata exchanged between the UEs. These and many other features and examples are described herein and can be enabled by the configurations, instructions, and/or other types of information stored by memory 904G.

In some implementations, the baseband circuitry 904 can include one or more audio digital signal processor(s) (DSP) 904F. The audio DSPs 904F can include elements for compression/decompression and echo cancellation and can include other suitable processing elements in other implementations. Components of the baseband circuitry can be suitably combined in a single chip, a single chipset, or disposed on a same circuit board in some implementations. In some implementations, some or all of the constituent components of the baseband circuitry 904 and the application circuitry 902 can be implemented together such as, for example, on a system on a chip (SOC).

In some implementations, the baseband circuitry 904 can provide for communication compatible with one or more radio technologies. For example, in some implementations, the baseband circuitry 904 can support communication with a NG-RAN, an evolved universal terrestrial radio access network (EUTRAN) or other wireless metropolitan area networks (WMAN), a wireless local area network (WLAN), a wireless personal area network (WPAN), etc. Implementations in which the baseband circuitry 904 is configured to support radio communications of more than one wireless protocol can be referred to as multi-mode baseband circuitry.

RF circuitry 906 can enable communication with wireless networks using modulated electromagnetic radiation through a non-solid medium. In various implementations, the RF circuitry 906 can include switches, filters, amplifiers, etc. to facilitate the communication with the wireless network. RF circuitry 906 can include a receive signal path which can include circuitry to down-convert RF signals received from the FEM circuitry 908 and provide baseband signals to the baseband circuitry 904. RF circuitry 906 can also include a transmit signal path which can include circuitry to up-convert baseband signals provided by the baseband circuitry 904 and provide RF output signals to the FEM circuitry 908 for transmission.

In some implementations, the receive signal path of the RF circuitry 906 can include mixer circuitry 906A, amplifier circuitry 906B and filter circuitry 906C. In some implementations, the transmit signal path of the RF circuitry 906 can include filter circuitry 906C and mixer circuitry 906A. RF circuitry 906 can also include synthesizer circuitry 906D for synthesizing a frequency for use by the mixer circuitry 906A of the receive signal path and the transmit signal path. In some implementations, the mixer circuitry 906A of the receive signal path can be configured to down-convert RF signals received from the FEM circuitry 908 based on the synthesized frequency provided by synthesizer circuitry 906D. The amplifier circuitry 906B can be configured to amplify the down-converted signals and the filter circuitry 906C can be a low-pass filter (LPF) or band-pass filter (BPF) configured to remove unwanted signals from the down-converted signals to generate output baseband signals. Output baseband signals can be provided to the baseband circuitry 904 for further processing. In some implementations, the output baseband signals can be zero-frequency baseband signals, although this is not a requirement. In some implementations, mixer circuitry 906A of the receive signal path can comprise passive mixers, although the scope of the implementations is not limited in this respect.

In some implementations, the mixer circuitry 906A of the transmit signal path can be configured to up-convert input baseband signals based on the synthesized frequency provided by the synthesizer circuitry 906D to generate RF output signals for the FEM circuitry 908. The baseband signals can be provided by the baseband circuitry 904 and can be filtered by filter circuitry 906C.

In some implementations, the mixer circuitry 906A of the receive signal path and the mixer circuitry 906A of the transmit signal path can include two or more mixers and can be arranged for quadrature down conversion and up conversion, respectively. In some implementations, the mixer circuitry 906A of the receive signal path and the mixer circuitry 906A of the transmit signal path can include two or more mixers and can be arranged for image rejection (e.g., Hartley image rejection). In some implementations, the mixer circuitry 906A of the receive signal path and the mixer circuitry 1406A can be arranged for direct down conversion and direct up conversion, respectively. In some implementations, the mixer circuitry 906A of the receive signal path and the mixer circuitry 906A of the transmit signal path can be configured for super-heterodyne operation.

In some implementations, the output baseband signals, and the input baseband signals can be analog baseband signals, although the scope of the implementations is not limited in this respect. In some alternate implementations, the output baseband signals, and the input baseband signals can be digital baseband signals. In these alternate implementations, the RF circuitry 906 can include analog-to-digital converter (ADC) and digital-to-analog converter (DAC) circuitry and the baseband circuitry 904 can include a digital baseband interface to communicate with the RF circuitry 906.

In some dual-mode implementations, a separate radio IC circuitry can be provided for processing signals for each spectrum, although the scope of the implementations is not limited in this respect.

In some implementations, the synthesizer circuitry 906D can be a fractional-N synthesizer or a fractional N/N+1 synthesizer, although the scope of the implementations is not limited in this respect as other types of frequency synthesizers can be suitable. For example, synthesizer circuitry 906D can be a delta-sigma synthesizer, a frequency multiplier, or a synthesizer comprising a phase-locked loop with a frequency divider.

The synthesizer circuitry 906D can be configured to synthesize an output frequency for use by the mixer circuitry 906A of the RF circuitry 906 based on a frequency input and a divider control input. In some implementations, the synthesizer circuitry 906D can be a fractional N/N+1 synthesizer.

In some implementations, frequency input can be provided by a voltage-controlled oscillator (VCO), although that is not a requirement. Divider control input can be provided by either the baseband circuitry 904 or the applications circuitry 902 depending on the desired output frequency. In some implementations, a divider control input (e.g., N) can be determined from a look-up table based on a channel indicated by the applications circuitry 902.

Synthesizer circuitry 906D of the RF circuitry 906 can include a divider, a delay-locked loop (DLL), a multiplexer and a phase accumulator. In some implementations, the divider can be a dual modulus divider (DMD) and the phase accumulator can be a digital phase accumulator (DPA). In some implementations, the DMD can be configured to divide the input signal by either N or N+1 (e.g., based on a carry out) to provide a fractional division ratio. In some example implementations, the DLL can include a set of cascaded, tunable, delay elements, a phase detector, a charge pump and a D-type flip-flop. In these implementations, the delay elements can be configured to break a VCO period up into Nd equal packets of phase, where Nd is the number of delay elements in the delay line. In this way, the DLL provides negative feedback to help ensure that the total delay through the delay line is one VCO cycle.

In some implementations, synthesizer circuitry 906D can be configured to generate a carrier frequency as the output frequency, while in other implementations, the output frequency can be a multiple of the carrier frequency (e.g., twice the carrier frequency, four times the carrier frequency) and used in conjunction with quadrature generator and divider circuitry to generate multiple signals at the carrier frequency with multiple different phases with respect to each other. In some implementations, the output frequency can be a LO frequency (fLO). In some implementations, the RF circuitry 906 can include an IQ/polar converter.

FEM circuitry 908 can include a receive signal path which can include circuitry configured to operate on RF signals received from one or more antennas 910, amplify the received signals and provide the amplified versions of the received signals to the RF circuitry 906 for further processing. FEM circuitry 908 can also include a transmit signal path which can include circuitry configured to amplify signals for transmission provided by the RF circuitry 906 for transmission by one or more of the one or more antennas 910. In various implementations, the amplification through the transmit or receive signal paths can be done solely in the RF circuitry 906, solely in the FEM circuitry 908, or in both the RF circuitry 906 and the FEM circuitry 908.

In some implementations, the FEM circuitry 908 can include a TX/RX switch to switch between transmit mode and receive mode operation. The FEM circuitry can include a receive signal path and a transmit signal path. The receive signal path of the FEM circuitry can include an LNA to amplify received RF signals and provide the amplified received RF signals as an output (e.g., to the RF circuitry 906). The transmit signal path of the FEM circuitry 908 can include a power amplifier (PA) to amplify input RF signals (e.g., provided by RF circuitry 906), and one or more filters to generate RF signals for subsequent transmission (e.g., by one or more of the one or more antennas 910).

In some implementations, the PMC 912 can manage power provided to the baseband circuitry 904. In particular, the PMC 912 can control power-source selection, voltage scaling, battery charging, or DC-to-DC conversion. The PMC 912 can often be included when the device 900 is capable of being powered by a battery, for example, when the device is included in a UE. The PMC 912 can increase the power conversion efficiency while providing desirable implementation size and heat dissipation characteristics.

While FIG. 9 shows the PMC 912 coupled only with the baseband circuitry 904. However, in other implementations, the PMC 912 can be additionally or alternatively coupled with, and perform similar power management operations for, other components such as, but not limited to, application circuitry 902, RF circuitry 906, or FEM circuitry 908.

In some implementations, the PMC 912 can control, or otherwise be part of, various power saving mechanisms of the device 900. For example, if the device 900 is in an RRC_Connected state, where it is still connected to the RAN node as it expects to receive traffic shortly, then it can enter a state known as discontinuous reception mode (DRX) after a period of inactivity. During this state, the device 900 can power down for brief intervals of time and thus save power.

If there is no data traffic activity for an extended period, then the device 900 can transition off to an RRC_Idle state, where it disconnects from the network and does not perform operations such as channel quality feedback, handover, etc. The device 900 goes into a very low power state and it performs paging where again it periodically wakes up to listen to the network and then powers down again. The device 900 may not receive data in this state; in order to receive data, it can transition back to RRC_Connected state.

An additional power saving mode can allow a device to be unavailable to the network for periods longer than a paging interval (ranging from seconds to a few hours). During this time, the device is unreachable to the network and can power down completely. Any data sent during this time incurs a large delay and it is assumed the delay is acceptable.

Processors of the application circuitry 902 and processors of the baseband circuitry 904 can be used to execute elements of one or more instances of a protocol stack. For example, processors of the baseband circuitry 904, alone or in combination, can be used execute Layer 3, Layer 2, or Layer 1 functionality, while processors of the baseband circuitry 904 can utilize data (e.g., packet data) received from these layers and further execute Layer 4 functionality (e.g., transmission communication protocol (TCP) and user datagram protocol (UDP) layers). As referred to herein, Layer 3 can comprise a RRC layer, described in further detail below. As referred to herein, Layer 2 can comprise a medium access control (MAC) layer, a radio link control (RLC) layer, and a packet data convergence protocol (PDCP) layer, described in further detail below. As referred to herein, Layer I can comprise a physical (PHY) layer of a UE/RAN node, described in further detail below.

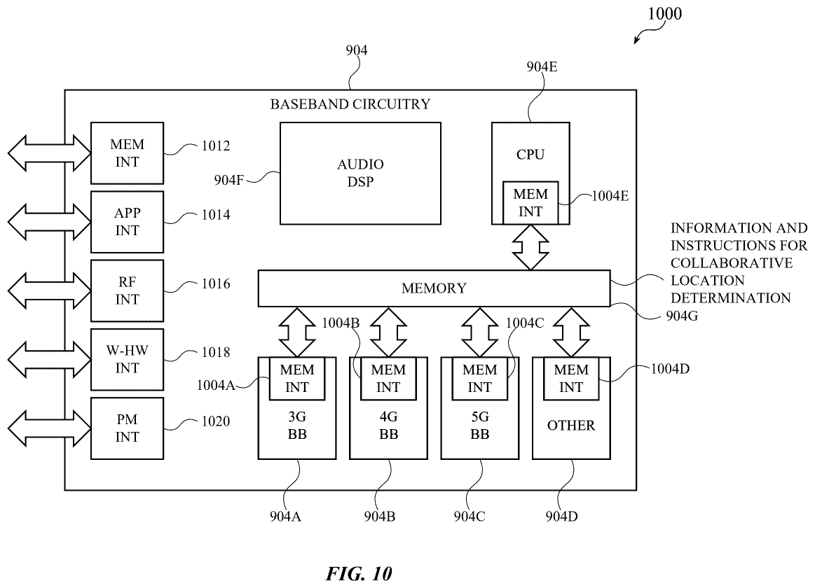

FIG. 10 is a diagram of example interfaces of baseband circuitry according to one or more implementations described herein. As discussed above, the baseband circuitry 1004 of FIG. 10 can comprise processors 1004A through 1004E and a memory 1004G utilized by said processors. Each of the processors 1004A through 1004E can include a memory interface, 1004A through 1004E, respectively, to send/receive data to/from the memory 1004G.

The baseband circuitry 1004 can further include one or more interfaces to communicatively couple to other circuitries/devices, such as a memory interface 1012 (e.g., an interface to send/receive data to/from memory external to the baseband circuitry 1004), an application circuitry interface 1014 (e.g., an interface to send/receive data to/from the application circuitry 902 of FIG. 9), an RF circuitry interface 1016 (e.g., an interface to send/receive data to/from RF circuitry 906 of FIG. 9), a wireless hardware connectivity interface 1018 (e.g., an interface to send/receive data to/from Near Field Communication (NFC) components, Bluetooth® components (e.g., Bluetooth® Low Energy), Wi-Fi® components, and other communication components), and a power management interface 1020 (e.g., an interface to send/receive power or control signals to/from the PMC 912).

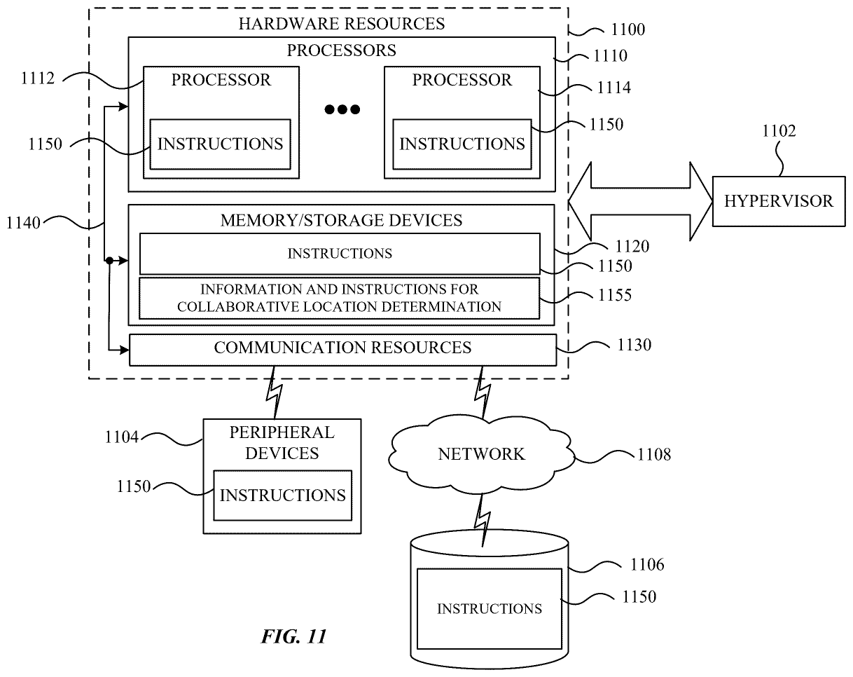

FIG. 11 is a block diagram illustrating components, according to some example implementations, able to read instructions from a machine-readable or computer-readable medium (e.g., a non-transitory machine-readable storage medium) and perform any one or more of the methodologies discussed herein. Specifically, FIG. 11 shows a diagrammatic representation of hardware resources 1100 including one or more processors (or processor cores) 1110, one or more memory/storage devices 1120, and one or more communication resources 1130, each of which can be communicatively coupled via a bus 1140. For implementations where node virtualization (e.g., NFV) is utilized, a hypervisor can be executed to provide an execution environment for one or more network slices/sub-slices to utilize the hardware resources 1100.

The processors 1110 (e.g., a central processing unit (CPU), a reduced instruction set computing (RISC) processor, a complex instruction set computing (CISC) processor, a graphics processing unit (GPU), a digital signal processor (DSP) such as a baseband processor, an application specific integrated circuit (ASIC), a radio-frequency integrated circuit (RFIC), another processor, or any suitable combination thereof) can include, for example, a processor 1112 and a processor 1114.

The memory/storage devices 1120 can include main memory, disk storage, or any suitable combination thereof. The memory/storage devices 1120 can include, but are not limited to any type of volatile or non-volatile memory such as dynamic random-access memory (DRAM), static random-access memory (SRAM), erasable programmable read-only memory (EPROM), electrically erasable programmable read-only memory (EEPROM), Flash memory, solid-state storage, etc.

In some implementations, memory/storage devices 1120 can receive and store one or more configurations, instructions, and/or other types of information 1155 to enable collaborative estimation of UE location. When the is determined to be moving with other UEs, the UEs can form a group. The UEs can determine their location collaboratively, based on location information and/or location information metadata exchanged between the UEs. These and many other features and examples are described herein and can be enabled by the configurations, instructions, and/or other types of information stored by memory/storage devices 1120.

The communication resources 1130 can include interconnection or network interface components or other suitable devices to communicate with one or more peripheral devices 1104 or one or more databases 1106 via a network 1108. For example, the communication resources 1130 can include wired communication components (e.g., for coupling via a universal serial bus (USB)), cellular communication components, NFC components, Bluetooth® components (e.g., Bluetooth® low energy), Wi-Fi® components, and other communication components.

Instructions 1150 can comprise software, a program, an application, an applet, an app, or other executable code for causing at least any of the processors 1110 to perform any one or more of the methodologies discussed herein. The instructions 1150 can reside, completely or partially, within at least one of the processors 1110 (e.g., within the processor's cache memory), the memory/storage devices 1120, or any suitable combination thereof. Furthermore, any portion of the instructions 1150 can be transferred to the hardware resources 1100 from any combination of the peripheral devices 1104 or the databases 1106. Accordingly, the memory of processors 1110, the memory/storage devices 1120, the peripheral devices 1104, and the databases 1106 are examples of computer-readable and machine-readable media.

Examples herein can include subject matter such as a method, means for performing acts or blocks of the method, at least one machine-readable medium including executable instructions that, when performed by a machine (e.g., a processor (e.g., processor, etc.) with memory, an application-specific integrated circuit (ASIC), a field programmable gate array (FPGA), or the like) cause the machine to perform acts of the method or of an apparatus or system for concurrent communication using multiple communication technologies according to implementations and examples described.

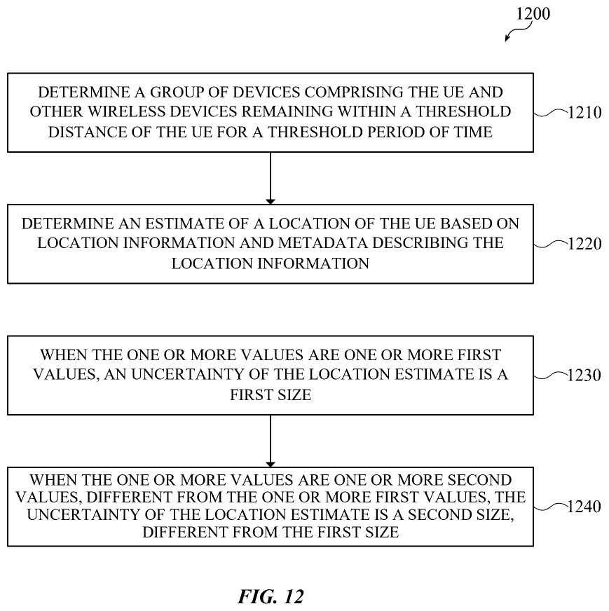

FIG. 12 is a diagram of a process of a UE determining a location estimate according to one or more implementations described herein. Process 1200 can be implemented by UE 210. In some implementations, some or all of process 1200 can be performed by one or more other systems or devices, including one or more of the devices of FIG. 2. Additionally, process 1200 can include one or more fewer, additional, differently ordered and/or arranged operations than those shown in FIG. 12. In some implementations, some or all of the operations of process 1200 can be performed independently, successively, simultaneously, etc., of one or more of the other operations of process 1200. As such, the techniques described herein are not limited to a number, sequence, arrangement, timing, etc., of the operations or processes depicted in FIG. 12. Example process 1200 can include determining a group of devices comprising the UE and one or more other wireless devices remain within a threshold distance of one another for a period of time greater than a threshold period of time (at 1210). The process 1200 can include determining an estimate of a location of the UE based on location information and location metadata describing the location information (at 1220). Process 1200 can include, when one or more values of the location information and/or metadata include one or more first values, an uncertainty of the location estimate is a first size (at 1230). Process 1200 can include, when the one or more values include one or more second values, the uncertainty of the location estimate is a second size (at 1240).

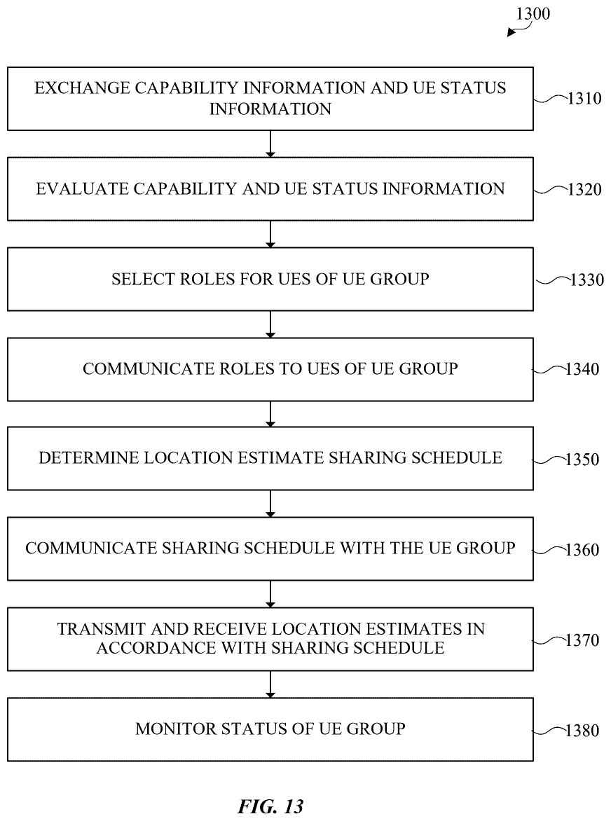

FIG. 13 is a diagram of an example process 1300 to determine, distribute, and implement a location estimate sharing schedule with a UE group according to one or more implementations described herein. Process 1300 can be implemented by UE 210. In some implementations, some or all of process 1300 can be performed by one or more other systems or devices, including one or more of the devices of FIG. 2. Additionally, process 1300 can include one or more fewer, additional, differently ordered and/or arranged operations than those shown in FIG. 13. In some implementations, some or all of the operations of process 1300 can be performed independently, successively, simultaneously, etc., of one or more of the other operations of process 1300. As such, the techniques described herein are not limited to a number, sequence, arrangement, timing, etc., of the operations or processes depicted in FIG. 13.

Process 1300 can include exchanging capability information and UE status information (at 1310). For example, UEs 210 can individually transmit information describing their processing power, processing usage, battery level, charging state, operating temperature, and/or some combination thereof to each other when included in a group.

Process 1300 can include evaluating capability and UE status information (at 1320). For example, UE 210-1 can receive the information from UEs 210, and can determine which UE(s) are connected to a charger, have a level of battery above a threshold level, have a level of processing availability above a threshold level, have an operating temperature below a threshold temperature, and/or can determine other characteristics of the UEs and/or their respective states relative to some criteria.

Process 1300 can include selecting a lead UE for a UE group (at 1330). For example, UE 210-1 can select UE 210-1 as the lead UE, which can be a UE responsible for determining a schedule of generating and/or sharing location estimates. UE 210-1 can detect that it is not connected to a charger while UE 210-2 is connected to a charger, and can select UE 210-2 as the lead UE given that the additional processing overhead required to coordinate location estimate generation and sharing is offset by the large power source UE 210-2 can be coupled to.

Process 1300 can include communicating a lead UE selection the group (at 1340). For example UE 210-1 can broadcast and/or individually transmit signals that UE 210-1 or UE 210-2 is the lead UE. In some implementations, UEs 210 can determine location estimate requirements. For example, UE 210-1 when elected the lead UE can determine whether a software application and/or firmware programmed into circuitry at a UE is likely to use a high-resolution location estimate, as described further with reference to FIGS. 6 and 7. As described above, UE 210-2 can be running a mapping application that will use a precise location estimate. UE 210-1 can accommodate the desire of UE 210-2 to obtain a precise location estimate by coordinating location estimate generation by the group of UEs 210s.

Process 1300 can include determining a location estimate sharing schedule (at 1350). For example, when UE 210-1 is the lead UE, UE 210-1 can generate a schedule designating which of UEs 210 is to generate a location estimate, which of UEs 210 is to generate a location estimate with a level of accuracy greater than a threshold level of accuracy, when UEs 210 will generate the location estimates, how often and/or how many times UEs 210 will repeat some or all operations to generate the location estimates, and/or the sequence that UEs 210 will take turns (or completely take responsibility for) providing location estimates with the group of UEs 210. For example, UE 210-1 can indicate that all UEs 210 will generate location estimates with a same periodicity, each offset by a period in time, as described further with reference to FIG. 8. Additionally or alternatively, UE 210-1 can indicate that UE 210-1 or another lone UE can generate the high-resolution location estimate for UEs 210. In some implementations, UE 210-1 can repeat the determining of the location estimate sharing schedule. For example, UE 210-1 can determine the schedule in a first instance when initiating location estimation, and in response to detecting a change to a state of a UE of UEs 210 and/or the group of UEs 210, can repeat the determining of the schedule. Process 1300 can include communicating a location estimate sharing schedule with the UE group (at 1360).

Process 1300 can include transmitting and/or receiving location estimates in accordance with the location estimate sharing scheduled (at 1370). The UEs of UEs 210 that receive the schedule can in response schedule times during which the individual UEs can activate high-resolution location sensing (e.g., using GPS or another highly precise localization technology) at the times designated by the scheduling information shared by UE 210-1. Additionally or alternatively, if another UE such as UE 210-2 is the lead UE, UE 210-1 can receive the scheduling information and act in accordance with the shared scheduling information. In some implementations, the scheduling information designates that UE 210-1 can remain in a current configuration, forgoing changing of an operating configuration (e.g., to generate a high-resolution location estimate), thus relying upon other UEs included in UEs 210 to provide the high-resolution location estimates.

Process 1300 can include monitoring a status the UE group (at 1380). For example, UE 210-1 can monitor whether an accuracy of location estimates is less than a threshold level of accuracy, that the accuracy of location estimates is not improving the combined location estimates generated at UE 210-1, that a signal strength, quality, and/or a SNR is above or below a threshold signal strength, quality, and/or SNR that implicates that the D2D protocol is subject to unwanted erroneous data communications, that a UE has moved outside a threshold distance and/or been removed from group of UEs 210, that a new UE has moved within the threshold distance and/or has joined the group of UEs 210, that a processing state, charging state, and/or a level of battery has changed in a manner and/or by an amount designated as indicating a trigger for reevaluating the group status, and/or some combination of factors thereof.

In some implementations, in response to detecting one or more of the aforementioned or other factors have changed, UE 210-1 can trigger a reevaluation of which UE of UEs 210 can be the lead UE, and/or whether the currently executed location estimate schedule is suitable for the current state of the UE group. For example, UE 210-1 can detect that a device that was previously providing a majority of the high-resolution estimates has left the UE group, and accordingly can repeat some or all of the operations described above. Additionally or alternatively, UE 210-2 can be the lead UE, but can leave the UE group. UE 210-1 can select another UE of UEs 210 that has the most battery, is coupled to a charger, has the most processing availability, is running the coolest operating temperature, and/or some combination of such factors (e.g., weighted in accordance with a predetermined formula to change a relative impact of the individual factor on lead UE selection). It is understood that in some implementations, some or all of the operations described as being performed by UE 210-1 and/or UE 210-2 can be performed partially or entirely by other UEs 210 in the UE group. For example, any suitable UE can be elected as the lead UE. Additionally or alternatively, the UEs 210 can exchange information to collectively determine a lead UE. After the lead UE is designated, the remaining operations included in process 1300 other than deciding on the lead UE can be executed at the lead UE (and/or offloaded to supporting UEs included in the UE group, instead of the lead UE).

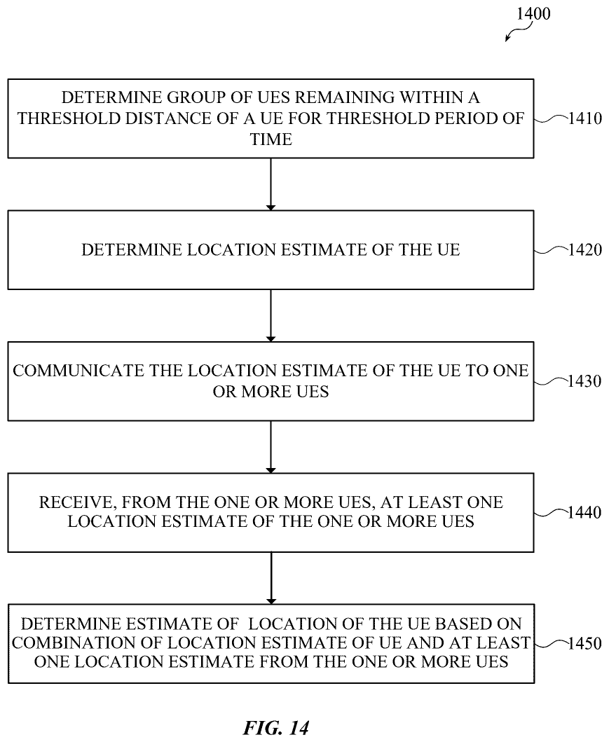

FIG. 14 is a diagram of a process 1400 of a UE determining a location estimate according to one or more implementations described herein. Process 1400 can be implemented by UE 210. In some implementations, some or all of process 1400 can be performed by one or more other systems or devices, including one or more of the devices of FIG. 2. Additionally, process 1400 can include one or more fewer, additional, differently ordered and/or arranged operations than those shown in FIG. 14. In some implementations, some or all of the operations of process 1400 can be performed independently, successively, simultaneously, etc., of one or more of the other operations of process 1400. As such, the techniques described herein are not limited to a number, sequence, arrangement, timing, etc., of the operations or processes depicted in FIG. 14.

As shown, process 1400 can include determining a group of devices comprising the UE and one or more other wireless devices remain within a threshold distance of one another for a period of time greater than a threshold period of time (at 1410). Process 1400 can include determining a location estimate of the UE (at 1420). Process 1400 can include communicating the location estimate of the UE to the one or more UEs (at 1430). Process 1400 can include receiving, from the one or more UEs, at least one location estimate of the one or more UEs (at 1440). Process 1400 can include determining an estimate of a location of the UE based on a combination of the location estimate of the UE and the at least one location estimate from the one or more UEs (at 1450).

In example 1, which can also include one or more of the examples described herein, a user equipment (UE) comprising memory and one or more processors can be configured to, when executing instructions stored in the memory, cause the UE to: determine a group of UEs comprising the UE and one or more other UEs remaining within a threshold distance of the UE for a threshold period of time, determine a location estimate of the UE, communicate the location estimate of the UE to the one or more UEs, receive, from the one or more UEs, at least one location estimate of the one or more UEs, and determine an estimate of a location of the UE based on a combination of the location estimate of the UE and the at least one location estimate from the one or more UEs.

In example 2, which can also include one or more of the examples described herein, the one or more processors can be configured to cause the UE to, determine whether the location estimate generated by the UE comprises a high-quality location estimate, when the location estimate generated by the UE comprises the high-quality location estimate, determine the estimate of the location of the UE based on the location estimate generated by the UE, when the location estimate generated by the UE does not comprises the high-quality location estimate, determine the estimate of the location of the UE based on the combination of the location estimate of the UE and the at least one location estimate from the one or more UEs. In example 3, which can also include one or more of the examples described herein, when the high-quality location estimate is required, receive the at least one location estimate of the one or more UEs, and determine the estimate of the location of the UE based on the combination of the location estimate of the UE and the at least one location estimate from the one or more UEs.

In example 4, which can also include one or more of the examples described herein, the one or more processors can be configured to cause the UE to, communicate the location estimate of the UE to the one or more UEs in response to determining that the location estimate generated by the UE comprises the high-quality location estimate, and refrain from communicating the location estimate of the UE to the one or more UEs in response to determining that the location estimate generated by the UE does not comprise the high-quality location estimate.

In example 5, which can also include one or more of the examples described herein, the one or more processors can be configured to cause the UE to, when the location estimate of the UE is unavailable, receive the at least one location estimate of the one or more UEs, and determine the estimate of the location of the UE based on the at least one location estimate from the one or more UEs.

In example 6, which can also include one or more of the examples described herein, the location estimate of the UE comprises a local location estimate. In example 7, which can also include one or more of the examples described herein, the one or more processors are configured to cause the UE to, determine a level of quality associated with the local location estimate, determine a level of quality associated with the estimate based on the combination, when the level of quality associated with the local location estimate is greater than the level of quality associated with the estimate based on the combination, discard the estimate based on the combination, and when the level of quality associated with the local location estimate is less than the level of quality associated with the estimate based on the combination, update one or more applications with the estimate based on the combination.

In example 8, which can also include one or more of the examples described herein, the one or more processors can be configured to cause the UE to, determine the level of quality associated with the local location estimate based on, an accuracy associated with the local location estimate, an age associated with the local location estimate, a motion state of UE, or a combination thereof.

In example 9, which can also include one or more of the examples described herein, the one or more processors can be configured to cause the UE to: determine the level of quality associated with the estimate based on the combination, based on: an accuracy associated with the at least one location estimate of the one or more UEs, an age associated with at least one location estimate of the one or more UEs, a motion state of the one or more UEs, or a combination thereof. In example 10, which can also include one or more of the examples described herein, the motion state of the UE comprises a velocity coinciding with determining the local location estimate, and the motion state of the one or more UEs comprises a velocity coinciding with receiving the at least one location estimate from the one or more UEs. In example 11, which can also include one or more of the examples described herein, the motion state of the UE comprises a category of mobility associated with a velocity coinciding with determining the local location estimate, and the motion state of the UE comprises a category of mobility associated with a velocity coinciding with receiving the at least one location estimate from the one or more UEs. In example, 12, which can also include one or more of the examples described herein, the age associated with the local location estimate comprises a time when the local location estimate was determined, and the age associated with the at least one location estimate from the one or more UEs comprises a time when the at least one location estimate was determined.

In example, 13, which can also include one or more of the examples described herein, the at least one location estimate comprises an estimated location of the one or more UEs.

In example, 14, which can also include one or more of the examples described herein, the location estimate of the UE comprises a first are of uncertainty determined by the UE, the at least one location estimate from the one or more UEs comprises at least one second area of uncertainty determined by the one or more UEs, and the estimate of the location of the UE based on the combination comprises a third area of uncertainty, the third area of uncertainty comprising a geographic where the first area of uncertainty overlaps with the at least one second area of uncertainty.

In example 15, which can also include one or more of the examples described herein, the one or more processors can be configured to cause the UE to: when the combination of the location estimate of the UE and the at least one location estimate from the one or more UEs satisfy one or more criteria, forgo performing of a global navigation satellite system (GNSS) scan.

In example 16, which can also include one or more of the examples described herein, the one or more processors can be configured to cause the UE to: when the combination of the location estimate of the UE and the at least one location estimate from the one or more UEs do not satisfy one or more criteria, and when the UE has last performed a first GNSS scan at a time beyond a threshold period of time, perform a second GNSS scan.

In example 17, which can also include one or more of the examples described herein, a first time that the UE determines the location estimate of the UE can be determined in accordance with a location estimate sharing schedule coordinated between the group of UEs.

In example 18, which can also include one or more of the examples described herein, the UE and the one or more other UEs can be included in the group of UEs in accordance with a determination a first user account logged into the UE can be associated with one or more second user accounts that can be logged into the one or more other UEs.

In example 19, which can also include one or more of the examples described herein, performed by a user equipment (UE), comprising: determining a group of UEs comprising the UE and one or more other UEs remaining within a threshold distance of the UE for a threshold period of time, determining a location estimate of the UE, communicating the location estimate of the UE to the one or more UEs, receiving, from the one or more UEs, at least one location estimate of the one or more UEs, and determining an estimate of a location of the UE based on a combination of the location estimate of the UE and the at least one location estimate from the one or more UEs.

In example 20, which can also include one or more of the examples described herein, a method can be performed at a user equipment (UE) comprising: determining a group of devices comprising the UE and one or more other wireless devices remaining within a threshold distance of the UE for a threshold period of time, determining an estimate of a location of the UE based on location information and metadata describing the location information, wherein the metadata includes one or more values that define one or more of: a distance between the UE and the one or more other wireless devices, an age of the location information, and motion states of the devices included in the group of devices when the location information can be detected, wherein estimating the location of the UE includes: when the one or more values can be one or more first values, an uncertainty of the location estimate can be a first size, and when the one or more values can be one or more second values, different from the one or more first values, the uncertainty of the location estimate can be a second size, different from the first size.

The above description of illustrated examples, implementations, aspects, etc., of the subject disclosure, including what is described in the Abstract, is not intended to be exhaustive or to limit the disclosed aspects to the precise forms disclosed. While specific examples, implementations, aspects, etc., are described herein for illustrative purposes, various modifications are possible that are considered within the scope of such examples, implementations, aspects, etc., as those skilled in the relevant art can recognize.

In this regard, while the disclosed subject matter has been described in connection with various examples, implementations, aspects, etc., and corresponding Figures, where applicable, it is to be understood that other similar aspects can be used or modifications and additions can be made to the disclosed subject matter for performing the same, similar, alternative, or substitute function of the subject matter without deviating therefrom. Therefore, the disclosed subject matter should not be limited to any single example, implementation, or aspect described herein, but rather should be construed in breadth and scope in accordance with the appended claims below.

In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations. In addition, while a particular feature can have been disclosed with respect to only one of several implementations, such feature can be combined with one or more other features of the other implementations as can be desired and advantageous for any given application.

As used herein, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form. Furthermore, to the extent that the terms “including”, “includes”, “having”, “has”, “with”, or variants thereof are used in either the detailed description or the claims, such terms are intended to be inclusive in a manner similar to the term “comprising.” Additionally, in situations wherein one or more numbered items are discussed (e.g., a “first X”, a “second X”, etc.), in general the one or more numbered items can be distinct, or they can be the same, although in some situations the context can indicate that they are distinct or that they are the same.

It is well understood that the use of personally identifiable information should follow privacy policies and practices that are generally recognized as meeting or exceeding industry or governmental requirements for maintaining the privacy of users. In particular, personally identifiable information data should be managed and handled to minimize risks of unintentional or unauthorized access or use, and the nature of authorized use should be clearly indicated to users.

What is claimed is:

1. A user equipment (UE) comprising:
one or more processors; and
memory storing instructions, which when executed by the one or more processors, cause the UE to:
exchange UE information with a group of UEs comprising the UE and one or more other UEs;
determine, based on the UE information, a lead UE for the group of UEs;
when the UE is determined to be the lead UE:
determine scheduling information for obtaining location estimates for the group of UEs, and
communicate the scheduling information to the one or more other UEs;
when the UE is not determined to be the lead UE:
receive, from the lead UE, the scheduling information;
generate a location estimate of the UE in accordance with the scheduling information, and
communicate the location estimate to at least one UE, of the one or more other UEs, in accordance with the scheduling information.

2. The UE of claim 1, wherein the UE information comprises:
a remaining battery power, a thermal state, a processing state, a charging state, or a combination thereof.

3. The UE of claim 1, wherein determining the lead UE is based on whether a remaining battery power of the UE or the one or more UEs satisfies a battery power threshold.

4. The UE of claim 1, wherein determining the lead UE is based on:
whether a thermal state of the UE or the one or more UEs satisfies a thermal state threshold,
whether a charging state of the UE or the one or more UEs satisfies a charging state threshold, or
a combination thereof.

5. The UE of claim 1, wherein determining the lead UE is based on whether a processing state of the UE or the one or more UEs satisfies a processing state threshold.

6. The UE of claim 1, wherein the scheduling information comprises an indication of when the UE and the one or more UEs are to:
obtain location estimates; and
communicate the location estimates to the group of UEs.

7. The UE of claim 1, wherein the scheduling information indicates a different time for each of the UE and the one or more UEs to obtain location estimates.

8. The UE of claim 1, wherein the instructions when executed by the one or more processors further cause the UE to:
monitor a state of the UE group,
detect at least one change to the state of the UE group,
update, based on the at least one change, the scheduling information, and
communicate the updated scheduling information to the UE group.

9. The UE of claim 8, wherein the at least one change comprises a change in a quantity of UEs included in the UE group.

10. The UE of claim 8, wherein the at least one change comprises a change in accuracy of location estimates provided by the UE or at least one UE of the one or more other UEs.

11. The UE of claim 8, wherein the at least one change comprises a change to:
a remaining battery power of the UE,
a remaining batter power of at least one UE of the one or more UEs,
a current temperature of the UE,
a current temperature of at least one UE of the one or more UEs, or
a combination thereof.

12. The UE of claim 1, wherein the scheduling information comprises an indication of a number of times and periodicity that the UE and the one or more UEs are to repeat generation and communication of location estimates.

13. The UE of claim 1, wherein determining the lead UE is based on a signal from the UE or at least one UE of the one or more UEs having a characteristics that satisfies one or more signal criteria.

14. The UE of claim 13, wherein the one or more signal criteria comprises:
a power of the signal, a quality of the signal, a signal-to-noise ration of the signal, a time-of-flight of the signal, or a combination thereof.

15. The UE of claim 1, wherein, when the UE is determined to be the lead UE, the one or more instructions when executed by the one or more processors further cause the UE to:
detect an event associated with changing the lead UE,
determine, in response to the event, an updated lead UE for the UE group, the updated lead UE comprising one UE of the one or more UEs,
transmit, to the one UE, an indication that the one UE is the updated lead UE,
receive updated scheduling information from the updated lead UE, and
generate location estimates in accordance with the updated scheduling information.

16. The UE of claim 1, wherein the scheduling information comprises timing information indicating when the UE is to generate the location estimate is based on one or more software applications executed by the UE.

17. The UE of claim 1, wherein:
when the UE is the lead UE,
a first UE of the one or more UEs is configured to generate location estimates according to a first UE configuration for generating location estimates,
the scheduling information comprises an indication of a time when the first UE is to be reconfigured according to a second UE configuration for generating location estimates,
the first UE configuration is different than the second UE configuration.

18. The UE of claim 17, wherein:
when configured in the first UE configuration, the first UE is configured to generate the location estimates with a first level of accuracy, and
when configured in the second UE configuration, the first UE is configured to generate the location estimates with a second level of accuracy, different from the first level of accuracy.

19. A non-transitory computer readable storage medium storing instructions, which when executed by a user equipment (UE) comprising one or more processors, cause the UE to:
exchange UE information with a group of UEs comprising the UE and one or more other UEs;
determine, based on the UE information, a lead UE for the group of UEs;
when the UE is determined to be the lead UE:
determine scheduling information for obtaining location estimates for the group of UEs, and
communicate the scheduling information to the one or more other UEs;
when the UE is not determined to be the lead UE:
receive, from the lead UE, the scheduling information;
generate a location estimate of the UE in accordance with the scheduling information; and
communicate the location estimate to at least one UE, of the one or more other UEs, in accordance with the scheduling information.

20. A method, performed by a user equipment (UE), comprising:
exchanging UE information with a group of UEs comprising the UE and one or more other UEs;
determining, based on the UE information, a lead UE for the group of UEs;
when the UE is determined to be the lead UE:
determining scheduling information for obtaining location estimates for the group of UEs, and
communicating the scheduling information to the one or more other UEs;
when the UE is not determined to be the lead UE:
receiving, from the lead UE, the scheduling information;
generating a location estimate of the UE in accordance with the scheduling information; and
communicating the location estimate to at least one UE, of the one or more other UEs, in accordance with the scheduling information.

21. The UE of claim 1, wherein the instructions when executed by the one or more processors further cause the UE to:
determine a first location estimate in accordance with the scheduling information,
receive a second location estimate in accordance with the scheduling information, and
determine a combined location estimate based on the first location estimate and the second location estimate.
